(19) United States
(12) Patent Application Publication
(10) Pub. No.: US 2026/0150382 A1
(43) Pub. Date: May 28, 2026

(54) PROTECTING LAYER FOR ISOLATION OF FEEDTHROUGH VIA

(71) Applicant: Taiwan Semiconductor Manufacturing Company, Ltd., Hsin-Chu (TW)

(72) Inventors: Yun-Shuo Chan, Hsinchu (TW); Po-Yu Huang, Hsinchu (TW); Yu-Chun Lin, Hsinchu (TW); Chen-Ming Lee, Yangmei City (TW); I-Wen Wu, Hsinchu City (TW); Mei-Yun Wang, Hsinchu (TW)

(21) Appl. No.: 19/169,267

(22) Filed: Apr. 3, 2025

Related U.S. Application Data
(60) Provisional application No. 63/725,032, filed on Nov. 26, 2024.

(51) Int. Cl. H10D 84/01; H10D 84/83

(52) U.S. Cl. CPC H10D 84/0153; H10D 84/013; H10D 84/0149; H10D 84/832

(57) ABSTRACT

A method includes providing a structure including a substrate and a fin-shaped structure protruding from the substrate, forming an isolation structure and a protecting layer thereon over the substrate and adjacent to a sidewall of the fin-shaped structure, growing a source/drain feature on a source/drain region of the fin-shaped structure, depositing a contact etch stop layer (CESL) over the source/drain feature, depositing a first interlayer dielectric (ILD) layer, a capping layer, and a second ILD layer over the CESL, forming a source/drain contact plug in the first ILD layer to electrically couple to the source/drain feature, forming a metal silicide layer between the source/drain feature and the source/drain contact plug, thinning down the substrate from a bottom of the structure, forming an opening exposing a bottom surface of the source/drain contact plug and a bottom surface of the protecting layer, and depositing a backside conductive feature in the opening.

### PRIORITY DATA

This application claims priority to U.S. Provisional Application No. 63/725,032 filed Nov. 26, 2024, the entirety of which is herein incorporated.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs and, for these advances to be realized, similar developments in IC processing and manufacturing are needed. Although existing structures and methods have been generally adequate for their intended purposes, they are not entirely satisfactory in every aspect.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a semiconductor structure, according to one or more aspects of the present disclosure.

FIG. 2 illustrates a fragmentary top view of an exemplary semiconductor structure during various fabrication stages in the method of FIG. 1, according to one or more aspects of the present disclosure.

FIGS. 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, and 44 illustrate fragmentary cross-sectional views of an exemplary semiconductor structure during various fabrication stages in the method of FIG. 1, according to one or more aspects of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

As the integrated circuits continue to scale down, so do the power rails. This inevitably leads to increased voltage drop across the power rails, as well as increased power consumption of the integrated circuits. One area of interest is how to form power rails and vias on the back side of an IC with reduced resistance and reduced coupling capacitance. The backside power rails may have wider dimension than the first level metal (M0) tracks on the frontside of the structure, which beneficially reduces the power rail resistance.

Feedthrough vias (FTV) are used to connect signals from the frontside of a wafer to the backside of the wafer. This allows for flexibility in forming semiconductor features on both front and backsides of a semiconductor structure. However, when surrounded by features such as active regions, metal gates, and conductive features, there are challenges in forming feedthrough vias. Therefore, although existing semiconductor structures have been generally adequate for their intended purposes, they have not been entirely satisfactory in all respects.

The present disclosure is generally related to semiconductor structures and fabrication processes, and more particularly to semiconductors having feedthrough vias (FTV) and a protecting layer to isolate the FTV from adjacent gate structures. In some embodiments, the structure disclosed herein includes a first active region and a second active region, an isolation structure disposed between the first and second active regions, a protecting layer disposed on the isolation structure, a gates structure disposed over and across the first and second active regions and interfacing a top surface of the protecting layer, and gate spacers disposed along sidewalls of the gate structure. In some embodiments, source/drain regions of the first and second active regions include source/drain features adjacent to the gate spacers. In some embodiments, the structure further includes source/drain contacts disposed over and electrically connected to the source/drain features, and an FTV disposed below and connected to the source/drain contacts. The FTV is spaced apart from the gate structure by the gate spacers and the protecting layer. By having the protecting layer, control of recessing a gate trench for the gate structure may be improved, direct contacting of the gate structure and the FTV is mitigated, and leakage window between the gate structure and the FTV may be increased.

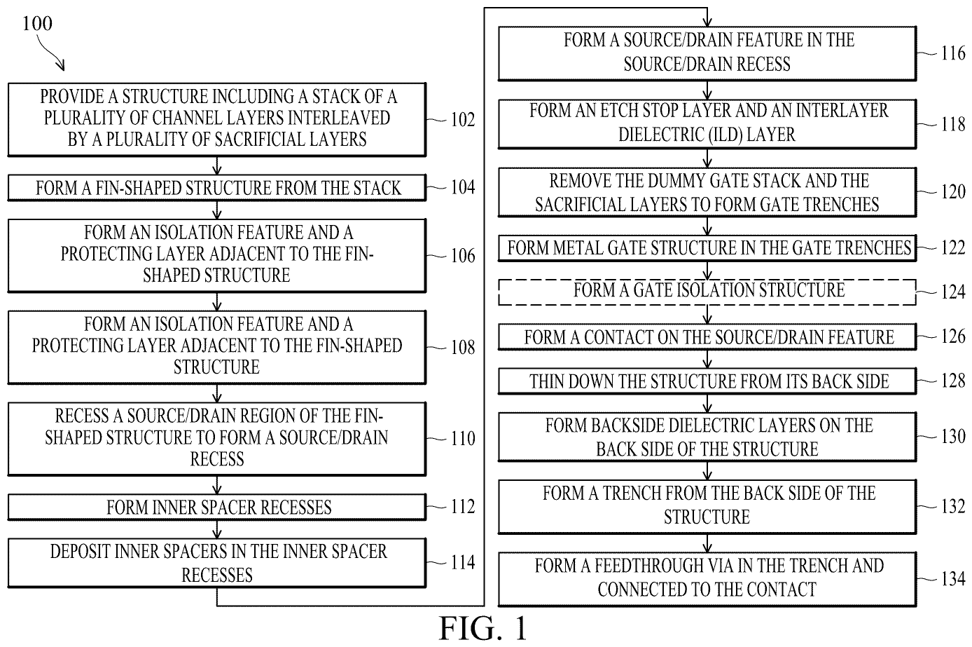

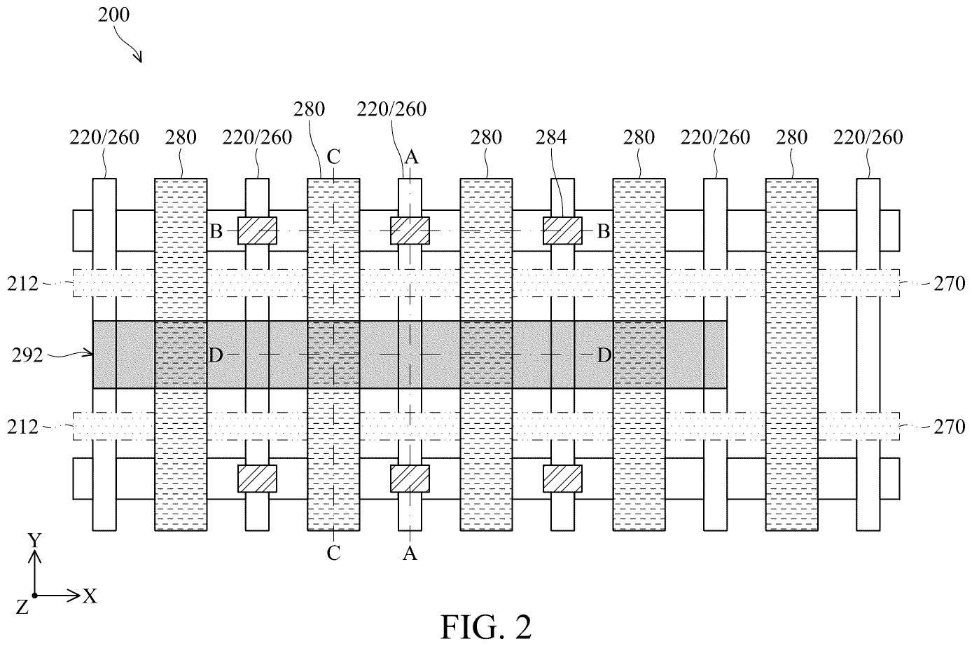

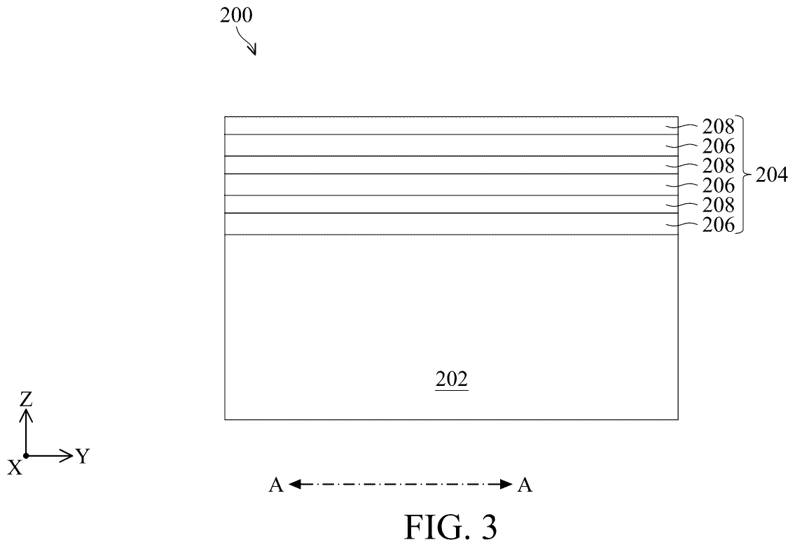

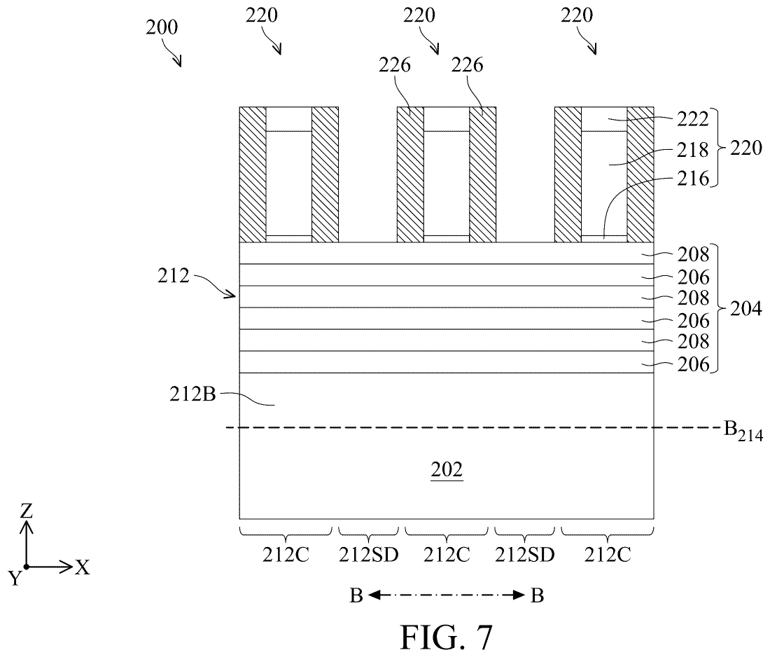

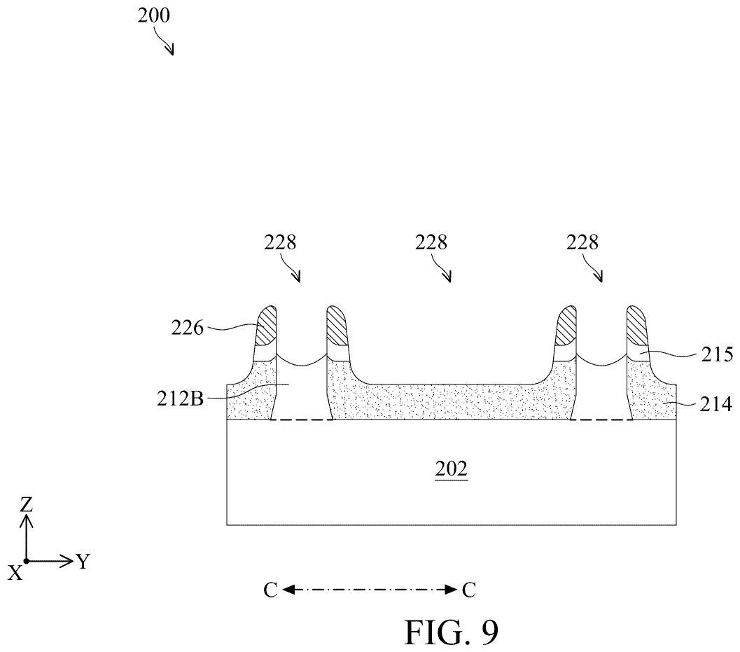

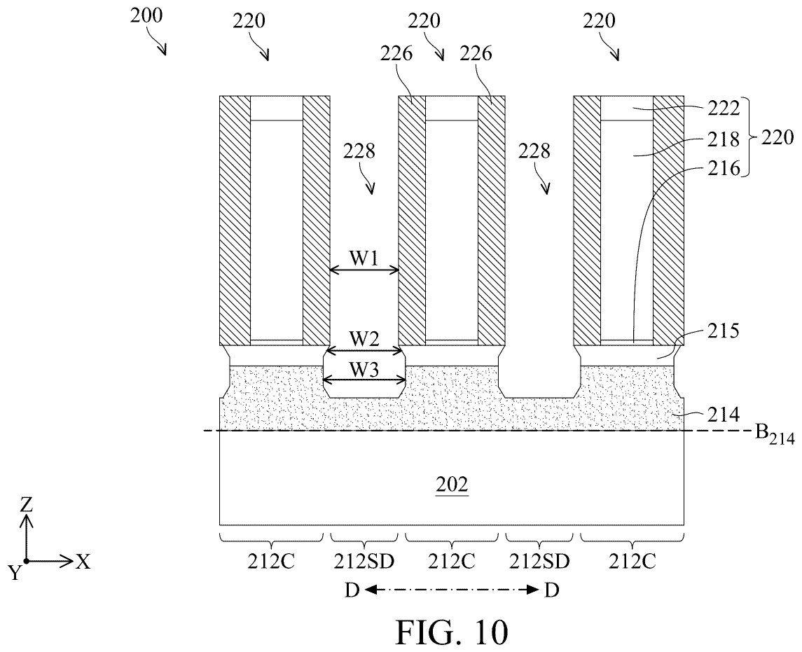

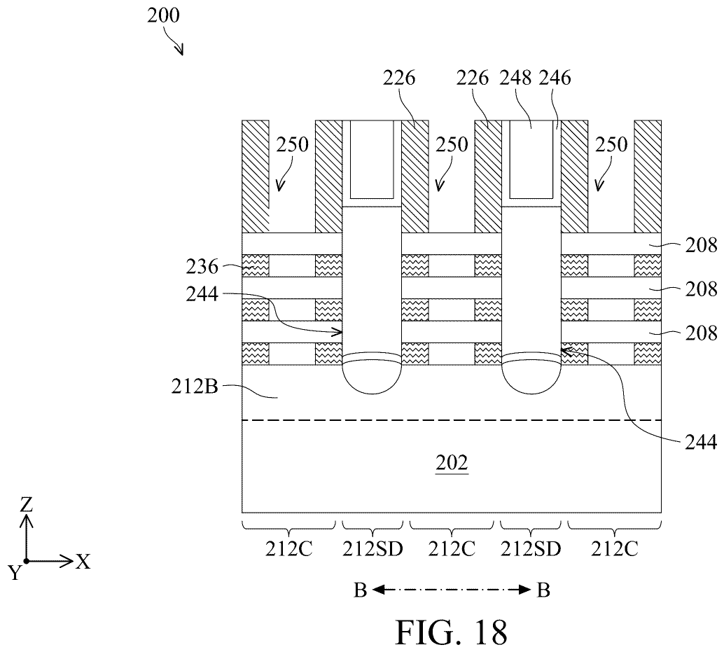

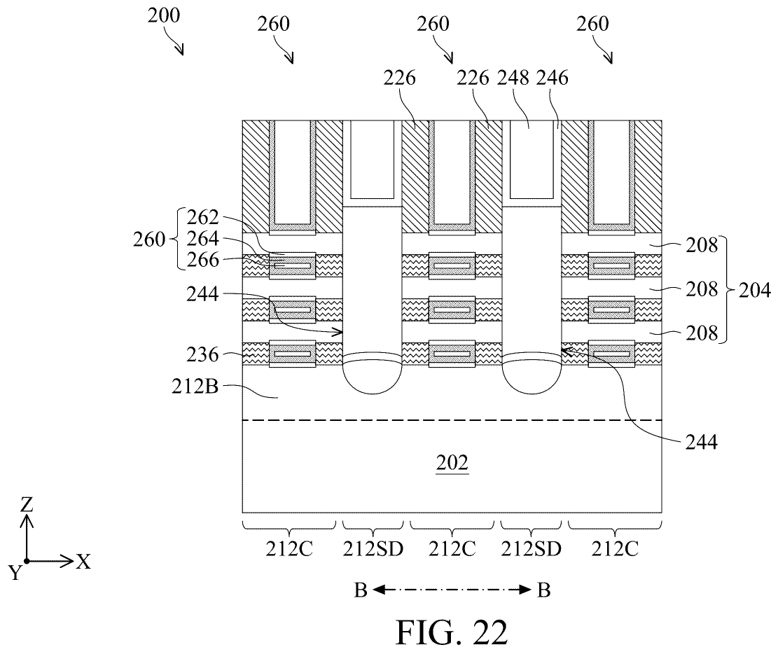

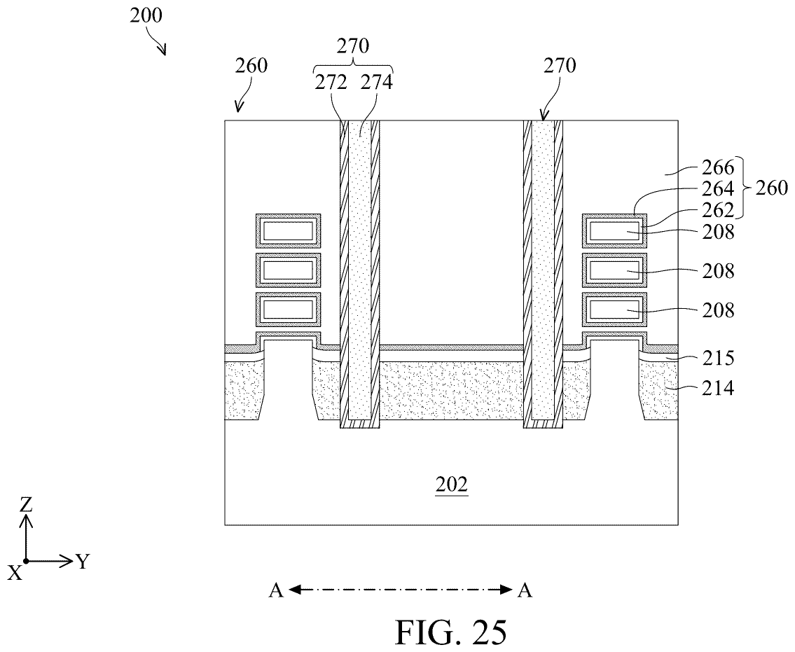

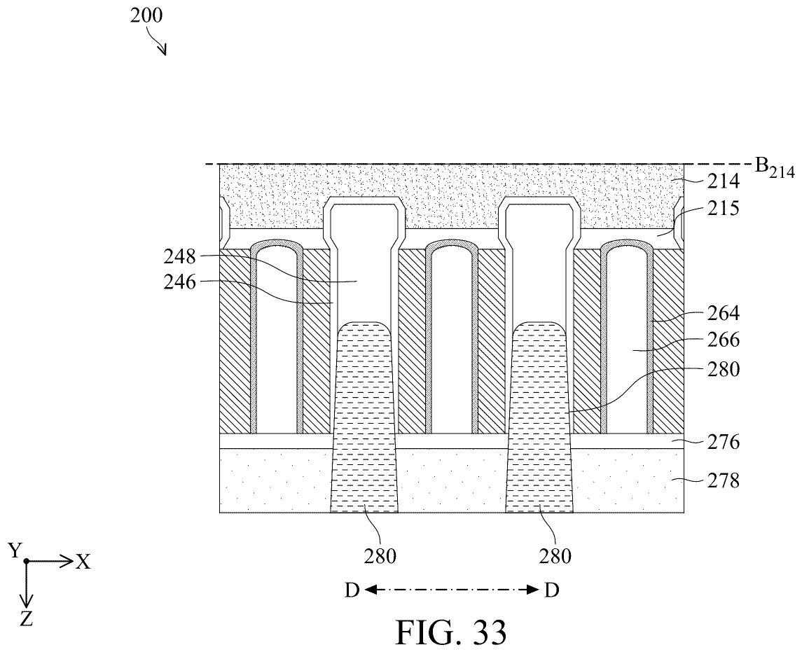

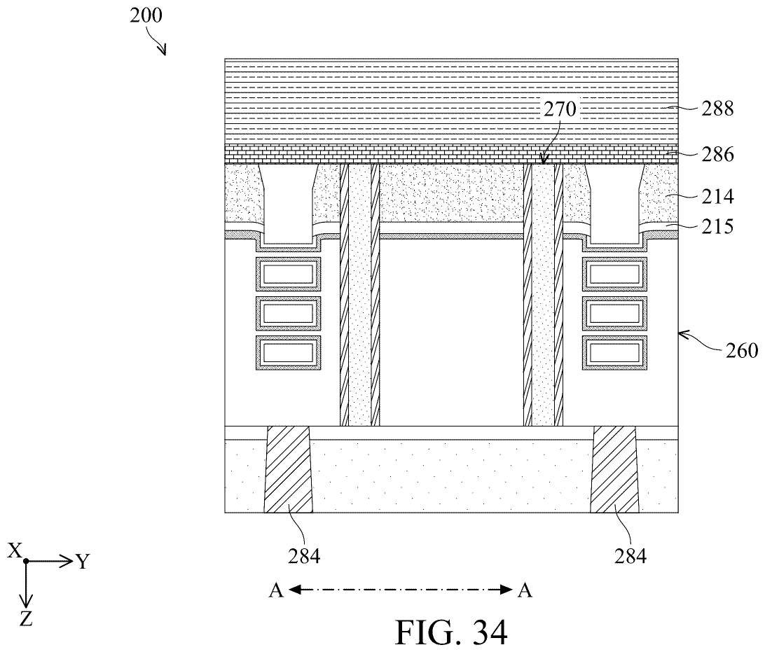

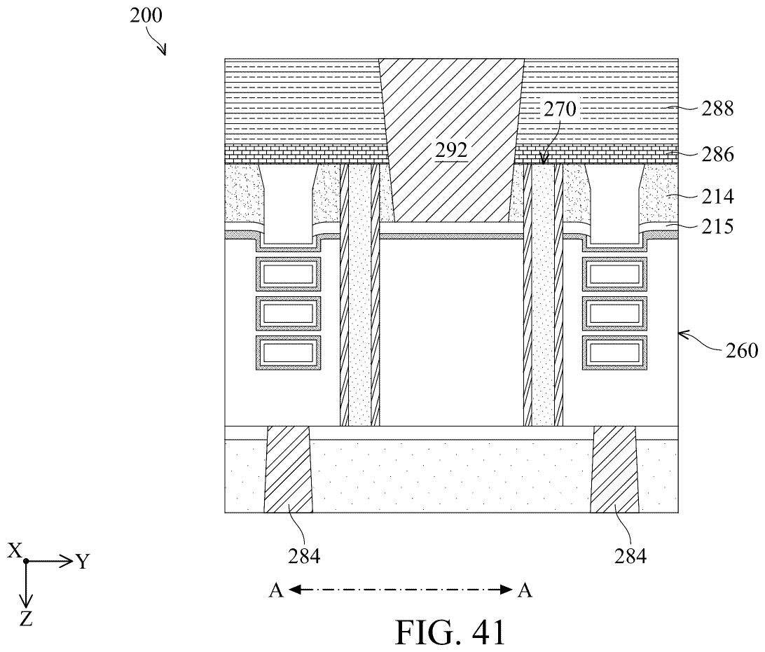

The various aspects of the present disclosure will now be described in more detail with reference to the figures. In that regard, FIG. 1 is a flowchart illustrating method 100 of forming a semiconductor structure according to embodiments of the present disclosure. Method 100 is described below in conjunction with FIGS. 2-44. FIG. 2 is a fragmentary top view of a structure 200 fabricated according to embodiments of method 100 in FIG. 1. FIGS. 3-44 are fragmentary cross-sectional views of the structure 200 at different stages of fabrication according to embodiments of method 100 in FIG. 1. FIGS. 3-6, 19, 23, 25, 29, 31, 34, 38, 41, 43, and 44 are fragmentary cross-sectional views taken along line A-A of FIG. 2, FIGS. 7-8, 12-14, 18, 22, 26, 30, and 32 are fragmentary cross-sectional views taken along line B-B of FIG. 2, FIGS. 9, 15, 28, 36, and 39 are fragmentary cross-sectional views taken along line C-C of FIG. 2, and FIGS. 10-11, 16-17, 20-21, 24, 27, 33, 35, 37, 40, and 42 are fragmentary cross-sectional views taken along line D-D of FIG. 2. Method 100 is merely an example and is not intended to limit the present disclosure to what is explicitly illustrated in method 100. Additional steps can be provided before, during and after method 100, and some steps described can be replaced, eliminated, or moved around for additional embodiments of method 100. Not all steps are described herein in detail for reasons of simplicity. Because the structure 200 will be fabricated into a semiconductor structure, the structure 200 may be referred to herein as a semiconductor structure 200 or a semiconductor device 200 as the context requires. For avoidance of doubts, the X, Y and Z directions in FIGS. 2-44 are perpendicular to one another and are used consistently throughout the present disclosure. Throughout the present disclosure, like reference numerals denote like features unless otherwise excepted. That is, material properties and comparisons thereof for various numbered elements described in association with a method or a figure should apply to the same numbered elements described in association with a different method or a different figure.

Referring to FIGS. 1 and 3, method 100 includes a block 102 where a structure 200 is formed or provided. The structure 200 includes a stack 204 of alternating semiconductor layers formed over a substrate 202.

In some embodiments, the substrate 202 may be a semiconductor substrate such as a silicon (Si) substrate. The substrate 202 may include various doping configurations depending on design requirements as is known in the art. In embodiments where the semiconductor device is p-type, an n-type doping profile (i.e., an n-type well or n-well) may be formed on the substrate 202. In some implementations, the n-type dopant for forming the n-type well may include phosphorus (P), arsenic (As), or antimony (Sb). In embodiments where the semiconductor device is n-type, a p-type doping profile (i.e., a p-type well or p-well) may be formed on the substrate 202. In some implementations, the p-type dopant for forming the p-type well may include boron (B) or gallium (Ga). The suitable doping may include ion implantation of dopants and/or diffusion processes. The substrate 202 may also include other semiconductors such as germanium (Ge), silicon carbide (SiC), silicon germanium (SiGe), germanium tin (GeSn), or diamond. Alternatively, the substrate 202 may include a compound semiconductor and/or an alloy semiconductor. Further, the substrate 202 may optionally include an epitaxial layer (epi-layer), may be strained for performance enhancement, may include a silicon-on-insulator (SOI) or a germanium-on-insulator (GeOI) structure, and/or may have other suitable enhancement features.

In some embodiments, the stack 204 atop the substrate 202 includes channel layers 208 of a first semiconductor composition interleaved by sacrificial layers 206 of a second semiconductor composition. It can also be said that the sacrificial layers 206 are interleaved by the channel layers 208. The first and second semiconductor compositions are different. In some embodiments, the sacrificial layers 206 include silicon germanium (SiGe) or germanium tin (GeSn) and the channel layers 208 include silicon (Si). It is noted that three (3) layers of the sacrificial layers 206 and three (3) layers of the channel layers 208 are alternately arranged as illustrated in FIG. 3, which is for illustrative purposes only and not intended to be limiting beyond what is specifically recited in the claims. It can be appreciated that any number of epitaxial layers may be formed in the stack 204. The number of layers depends on the performance needs for the semiconductor device 200. In some embodiments, the number of channel layers 208 is between 2 and 10.

The sacrificial layers 206 and channel layers 208 in the stack 204 may be deposited using a molecular beam epitaxy (MBE) process, a vapor phase deposition (VPE) process, and/or other suitable epitaxial growth processes. As stated above, in at least some examples, the sacrificial layers 206 include an epitaxially grown silicon germanium (SiGe) layer and the channel layers 208 include an epitaxially grown silicon (Si) layer. In some embodiments, Ge % in the sacrificial layers 206 may be not less than about 20%, such as about 30% or above. In some embodiments, the sacrificial layers 206 and the channel layers 208 are substantially dopant-free (i.e., having an extrinsic dopant concentration from about 0 atoms/cm³ to about 1×10¹⁷ atoms/cm³), where for example, no intentional doping is performed during the epitaxial growth processes for the stack 204.

Referring to FIGS. 1-2 and 4, method 100 includes a block 104 where fin-shaped structures 212 are formed from the stack 204 and the substrate 202.

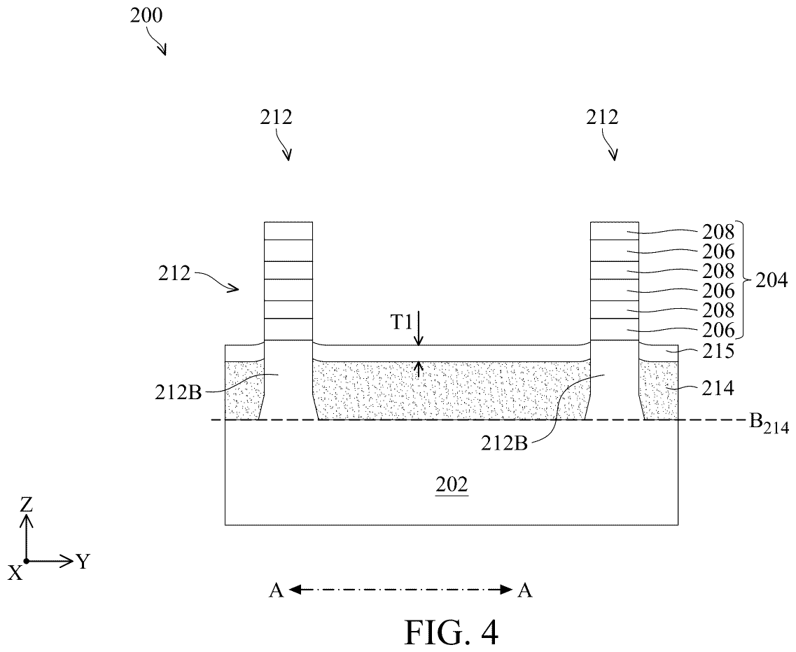

To pattern the stack 204, a hard mask layer may be deposited over the stack 204 to form an etch mask. The hard mask layer may be a single layer or a multi-layer. For example, the hard mask layer may include a pad oxide layer and a pad nitride layer disposed over the pad oxide layer. The fin-shaped structures 212 may be patterned from the stack 204 and the substrate 202 using a lithography process and an etching process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods. As shown in FIG. 4, the etching process at block 104 forms trenches extending vertically through the stack 204 and a portion of the substrate 202. The trenches define the fin-shaped structures 212. In some implementations, double-patterning or multi-patterning processes may be used to define fin-shaped structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shaped structure 212 by etching the stack 204 and a portion of the substrate 202. As shown in FIG. 4, the fin-shaped structure 212 extends vertically along the Z direction and lengthwise along the Y direction. The fin-shaped structure 212 provides an active region (also referred to as active region 212) for the subsequently-formed transistors, which includes channel regions (denoted as 212C, as shown in FIG. 7) and source/drain regions (denoted as 212SD, as shown in FIG. 7). As shown in FIG. 4, the fin-shaped structure 212 includes a fin-shaped base 212B patterned from the substrate 202 and the patterned stack 204 disposed directly over the fin-shaped base 212B. In the illustrated embodiment as shown in FIG. 4, the patterned stack 204 and the top portion of the fin-shaped base 212B have substantially straight sidewalls; while the bottom portion of the fin-shaped base 212B has tapering sidewalls due to loading effect during the patterning process.

Referring to FIGS. 1 and 4, method 100 includes a block 106 where an isolation structure 214 (or referred to as isolation feature 214) is formed around the fin-shaped base 212B of the fin-shaped structures 212, and a protecting layer 215 is formed over the isolation structure 214. A level B₂₁₄ of a bottom surface of the isolation structure 214 may be illustrated in a dashed line.

In some embodiments represented in FIG. 4, the isolation structure 214 is disposed on sidewalls of the fin-shaped base 212B. In some embodiments, the isolation structure 214 may be formed in the trenches to isolate adjacent active regions residing in the fin-shaped structures 212. In some embodiments, the isolation structure 214 is a shallow trench isolation (STI) feature 214. By way of example, in some embodiments, a dielectric layer is first deposited over the substrate 202, filling the trenches with the dielectric layer. In some embodiments, the dielectric layer may include silicon oxide, silicon oxynitride, fluorine-doped silicate glass (FSG), a low-k dielectric, combinations thereof, and/or other suitable materials. In some embodiments, the dielectric layer includes silicon oxide. In various examples, the dielectric layer may be deposited by a chemical vapor deposition (CVD) process, a subatmospheric CVD (SACVD) process, a flowable CVD process, a spin-on coating process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the isolation structure 214 shown in FIG. 4. In the illustrated embodiment, the top surface of the isolation structure 214 has a dishing profile due to loading effect during etching process. The fin-shaped structures 212 rise above the isolation structure 214 after the recessing, while the fin-shaped base 212B is at least partially embedded or buried in the isolation structure 214. In the illustrated embodiment, the top edge of the dishing profile of the isolation structure 214 intersects sidewalls of the fin-shaped base 212B.

Still referring to FIGS. 1 and 4, the protecting layer 215 is formed over the isolation structure 214 and around a top portion of the fin-shaped base 212B. A composition of the protecting layer 215 is different from a composition of the isolation structure 214. In some embodiments, the isolation structure 214 includes silicon oxide (SiOx, e.g., SiO₂), and the protecting layer 215 includes silicon nitride (SiₓN_{y}, e.g., SiN, Si₃N₄), silicon carbonitride (SiCN), or silicon oxynitride (SiON). The protecting layer 215 may have a concentration of nitrogen of about 50% to about 70%. By way of example, in some embodiments, a nitride-containing material is first deposited over the isolation structure 214, filling the trenches. In various examples, the nitride-containing material may be deposited by a CVD process, a subatmospheric CVD (SACVD) process, a flowable CVD process, a spin-on coating process, and/or other suitable process. The deposited nitride-containing material is then thinned and planarized, for example by a chemical mechanical polishing (CMP) process. The planarized nitride-containing material is further recessed or pulled-back by a dry etching process, a wet etching process, and/or a combination thereof to form the protecting layer 215. In the illustrated embodiment, the top surface of the protecting layer 215 has a dishing profile due to loading effect during etching process. The fin-shaped structures 212 rise above the protecting layer 215 after the recessing. In the illustrated embodiment, the top edge of the dishing profile of the protecting layer 215 intersects sidewalls of the fin-shaped base 212B. Alternatively, the top edge of the dishing profile of the protecting layer 215 may intersect sidewalls of the bottommost sacrificial layer 206, such that the fin-shaped base 212B is fully embedded or buried in a combination of the isolation structure 214 and the protecting layer 215. The middle point of the dishing profile (e.g., the lowest point of the top surface) of the protecting layer 215 may be below or alternatively above the bottom surface of the bottommost sacrificial layer 206. The fin-shaped base 212B is embedded or buried in the combination of the isolation structure 214 and the protecting layer 215. A thickness T1 of the protecting layer 215 may range from about 10 nm to about 50 nm, alternatively from about 30 nm to about 50 nm. This range is not arbitrary or trivial. If T1 is less than about 10 nm, the protecting layer 215 may itself be etched through due to limited etching contrast in subsequent etching processes and compromise the protection function to the isolation structure 214. If T1 is greater than about 50 nm, the bottommost sacrificial layer 206 may be buried thereunder and hard to be removed in subsequent replacement gate process.

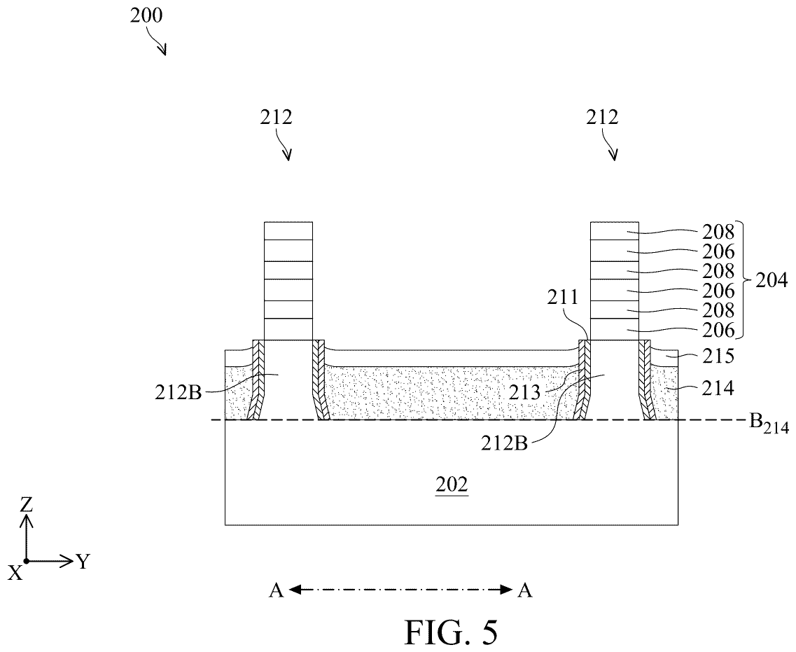

Referring to FIG. 5, in some alternative embodiments, before forming the isolation structure 214 and the protecting layer 215, a low nitrogen layer 211 and/or an oxide layer 213 may be formed along the sidewall of the fin-shaped base 212B. The low nitrogen layer 211 and the oxide layer 213 may each have different compositions from the protecting layer 215 and the isolation structure 214. In some embodiments, the low nitrogen layer 211 includes silicon nitride (e.g., SiₓN_{y}) and has a concentration of nitrogen less than about 10%, such as about 2% to about 10%. In some embodiments, the oxide layer 213 includes a high temperature oxide material. In some embodiments, the oxide layer 213 includes silicon oxide (SiOx, e.g., SiO₂) and has a concentration of oxygen different from (e.g., greater than) a concentration of oxygen in the isolation structure 214. In some embodiments, the oxide layer 213 includes a concentration of SiO₂ greater than a concentration of SiO₂ in the isolation structure 214. By way of example, the low nitrogen layer 211 may be formed by blanket depositing a dielectric material layer in a conformal manner over the structure 200 using processes such as, a chemical vapor deposition (CVD) process, a subatmospheric CVD (SACVD) process, an atomic layer deposition (ALD) process, a physical vapor deposition (PVD) process, or other suitable process. In the illustrated embodiment, the deposition of the dielectric material layer is followed by an etching-back (e.g., anisotropically) process to remove the dielectric material layer from horizontal surface(s) and from sidewalls of the patterned stack 204. In some embodiments, the etching-back process may include a wet etch process, a dry etch process, a multiple-step etch process, and/or a combination thereof. In some embodiments, the etching-back process includes a directional etching process (e.g., a tilted plasma etching), in which an ion beam may be directed to a surface of structure 200 with a tilt angle with respect to the Z-direction. In embodiments, the top surface and the sidewalls of the patterned stack 204 and the top surface of the substrate 202 in the trenches are exposed after the etching-back process. The dielectric material layer may remain on sidewalls of the fin-shaped base 212B, as the low nitrogen layer 211. The oxide layer 213 may be formed similarly by blanket depositing another dielectric material layer in a conformal manner over the structure 200 and performing an etching-back process. The low nitrogen layer 211 and the oxide layer 213 may each have a thickness of about 3 nm to about 7 nm. In some embodiments, the top edge of the dishing profile of the protecting layer 215 intersects sidewalls of the oxide layer 213. The low nitrogen layer 211 and the oxide layer 213 may protect the fin-shaped base 212B and the isolation structure 214 in the subsequent processes (e.g., when a dummy gate stack and the sacrificial layers 206 are removed). The low nitrogen layer 211 and the oxide layer 213 are not depicted in the following figures, but it is understood that they may be included in the structure 200 in the following figures.

Referring to FIGS. 1-2 and 6-7, method 100 includes a block 108 where dummy gate stacks 220 and gate spacers 226 are formed over channel regions 212C of the fin-shaped structure 212. The dummy gate stacks 220 serve as a placeholder to undergo various processes and are to be removed and replaced by functional gate structures. Other processes and configuration are possible. The dummy gate stacks 220 extend lengthwise along the Y-direction as in FIG. 2. As shown in FIG. 7, the dummy gate stacks 220 and gate spacers 226 are formed over the fin-shaped structure 212, and the fin-shaped structure 212 may be divided into channel regions 212C underlying the dummy gate stacks 220 and the gate spacers 226 and source/drain regions 212SD that do not underlie the dummy gate stacks 220 and the gate spacers 226. The channel regions 212C are adjacent to the source/drain regions 212SD. As shown in FIG. 7, the channel region 212C is disposed between two source/drain regions 212SD along the X-direction. As used herein, a source/drain region, or “S/D region,” may refer to a region that provides a source and/or drain for one or multiple devices. It may also refer to a source or a drain of one or multiple devices.

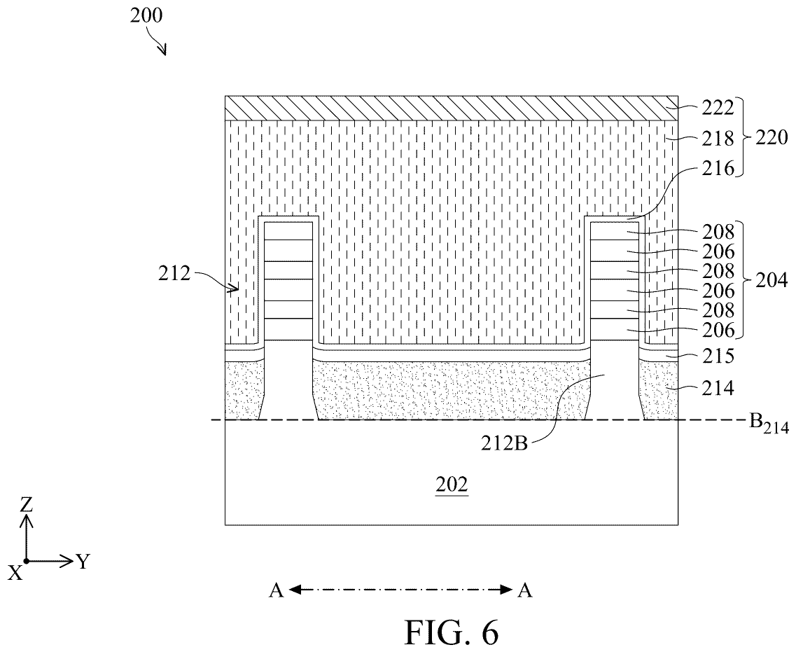

The formation of the dummy gate stack 220 may include deposition of layers in the dummy gate stack 220 and patterning of these layers. Referring to FIG. 6, a dummy dielectric layer 216, a dummy electrode layer 218, and a gate-top hard mask layer 222 may be blanketly deposited over the semiconductor device 200. The dummy dielectric layer 216 may be conformally deposited on the fin-shaped structure 212 using a chemical vapor deposition (CVD) process, an atomic layer deposition (ALD) process, an oxygen plasma oxidation process, or other suitable processes. The term “conformally” may be used herein for ease of description of a layer having substantially uniform thickness over various regions. In some instances, the dummy dielectric layer 216 may include silicon oxide. Thereafter, the dummy electrode layer 218 may be deposited over the dummy dielectric layer 216 using a CVD process, an ALD process, or other suitable processes. In some instances, the dummy electrode layer 218 may include polysilicon. For patterning purposes, the gate-top hard mask layer 222 may be deposited on the dummy electrode layer 218 using a CVD process, an ALD process, or other suitable processes. The gate-top hard mask layer 222, the dummy electrode layer 218 and the dummy dielectric layer 216 may then be patterned to form the dummy gate stacks 220, as shown in FIG. 7. For example, the patterning process may include a lithography process (e.g., photolithography or e-beam lithography) and an etching process. The lithography process may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The photolithography process forms a patterned photoresist layer. The patterned photoresist layer is then applied as an etch mask in the etching process to pattern the gate-top hard mask layer 222, the dummy electrode layer 218 and the dummy dielectric layer 216. In some embodiments, the etching process may include dry etching (e.g., RIE etching), wet etching, and/or other etching methods. In some embodiments, the gate-top hard mask layer 222 is a bi-layer structure, which may include a silicon oxide layer and a silicon nitride layer over the silicon oxide layer.

The formation of the gate spacers 226 may include deposition of a gate spacer layer and etching back the gate spacer layer. In some embodiments, the gate spacer layer is deposited conformally over the semiconductor device 200, including over top surfaces and sidewalls of the dummy gate stacks 220. The gate spacer layer may be a single layer or a multi-layer. The at least one layer in the gate spacer layer may include silicon carbonitride, silicon oxycarbide, silicon oxycarbonitride, or silicon nitride. The gate spacer layer may be deposited over the dummy gate stack 220 using processes such as, a CVD process, a subatmospheric CVD (SACVD) process, an ALD process, or other suitable process. Subsequently, an anisotropic etching process may be implemented to remove horizontal portions of the gate spacer layer from top-facing surfaces of the semiconductor device 200, including from top-surfaces of the dummy gate stacks 220. The remaining vertical portions of the gate spacer layer covers sidewalls of the dummy gate stacks 220 as the gate spacers 226.

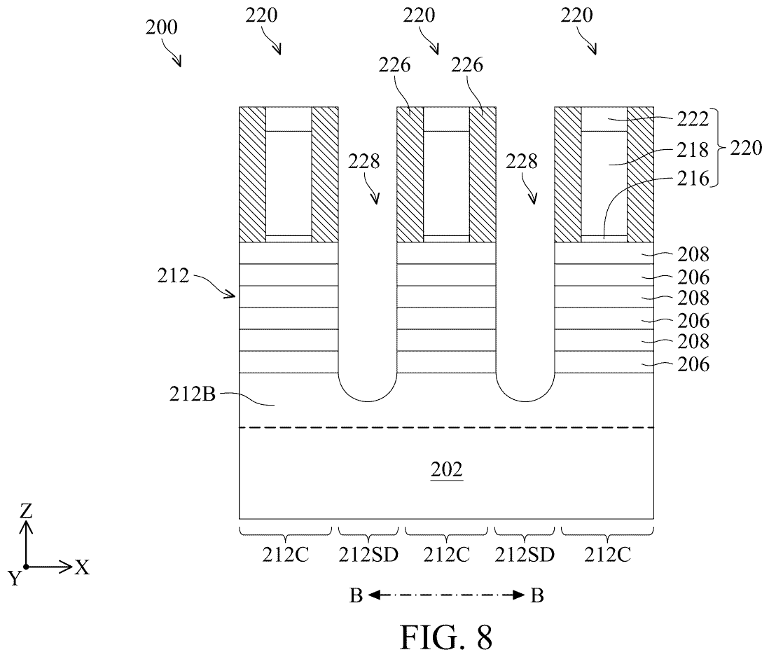

Referring to FIGS. 1 and 8-11, method 100 includes a block 110 where source/drain regions 212SD of the fin-shaped structure 212 are anisotropically recessed to form source/drain recesses 228. The anisotropic etch may include a dry etch or a suitable etching process that etches the source/drain regions 212SD and a portion of the substrate 202. The resulting source/drain recesses 228 extend vertically through the depth of the stack 204 and partially into the substrate 202 (i.e., the fin-shaped base 212B is partially recessed). An example dry etching process for block 110 may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As illustrated in FIG. 8, the source/drain regions 212SD of the fin-shaped structure 212 are recessed to expose sidewalls of the sacrificial layers 206 and the channel layers 208. Because the source/drain recesses 228 extend below the stack 204 into the substrate 202, the source/drain recesses 228 include bottom surfaces and lower sidewalls defined in the substrate 202.

As illustrated in FIG. 9, over the source/drain regions 212SD, the majority of the fin-shaped structure 212 is etched away and a top surface of the fin-shaped base 212B is exposed in the source/drain region 212SD. Further, the recessed top surface of the fin-shaped base 212B may be lower than a top surface of the protecting layer 215. Because the gate spacers 226 are etched at a slower rate than the fin-shaped structure 212, the gate spacers 226 in the source/drain region 212SD rise above the top surface of the fin-shaped base 212B. The remaining gate spacers 226 in the source/drain region 212SD are also referred to as fin spacers. The fin spacers protect portions of the protecting layer 215 directly underneath from being removed during the recessing of the source/drain regions 212SD.

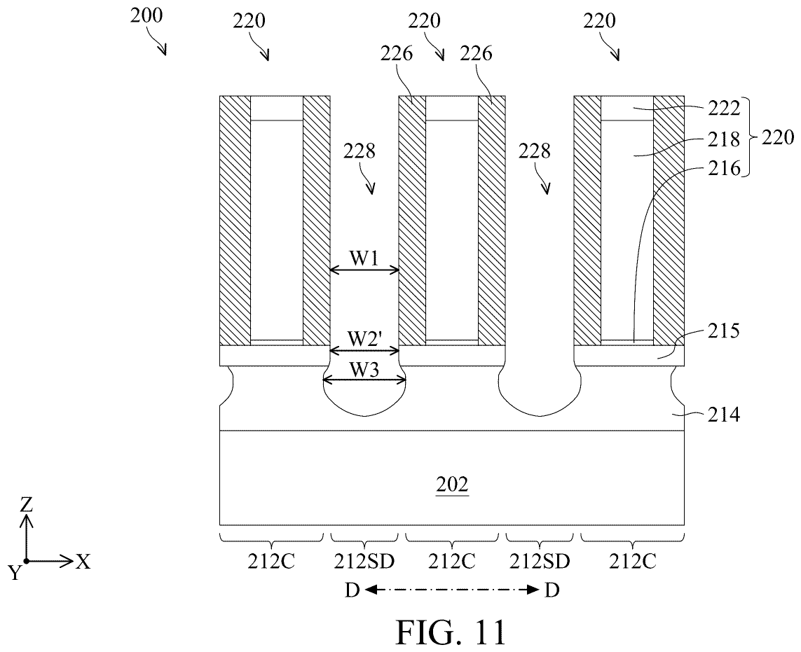

As illustrated in FIG. 10, between adjacent fin-shaped structures 212, the bottom surfaces of the dummy gate stacks 220 and the gate spacers 226 land directly on the top surface of the protecting layer 215. In the illustrated embodiment as shown in FIG. 10, the etching process performed during the recessing of the source/drain regions 212SD also etches through the protecting layer 215 between opposing gate spacers 226, and consequently the top portion of the isolation structure 214 after being exposed may also suffer some etch loss due to limited etching contrast. This etching process expands the cavity (i.e., the bottom portion of trench 228) beneath the protection layer 215, resulting in a cavity width that exceeds the lateral spacing between the opposing gate spacers 226. In other words, a portion of the cavity may extend directly beneath the gate spacers 226. Additionally, the bottom portion of the protection layer 215 may be laterally etched, causing the divided segments of the protection layer 215 to take on an inverted trapezoidal appearance. In some embodiments, the anisotropic etching process in removing horizontal portions of the gate spacer layer at block 108 may also etch at least a portion of the protecting layer 215 between the opposing gate spacers 226. In the depicted embodiment, the trench 228 may have a width W1 between the opposing gate spacers 226, a width W2 between the opposing protecting layers 215, and a width W3 between opposing sidewalls of the isolation structure 214. In some embodiments, W3 is greater than W2 and W2 is greater than W1. Referring to FIG. 11, in some alternative embodiments, the bottom portion of the protection layer 215 is not laterally etched. The trench 228 may have a width W2′ between the opposing protecting layers 215, W2′ may the same as W1 and less than W3. In some embodiments, the bottom surface of the trench 228 is curved.

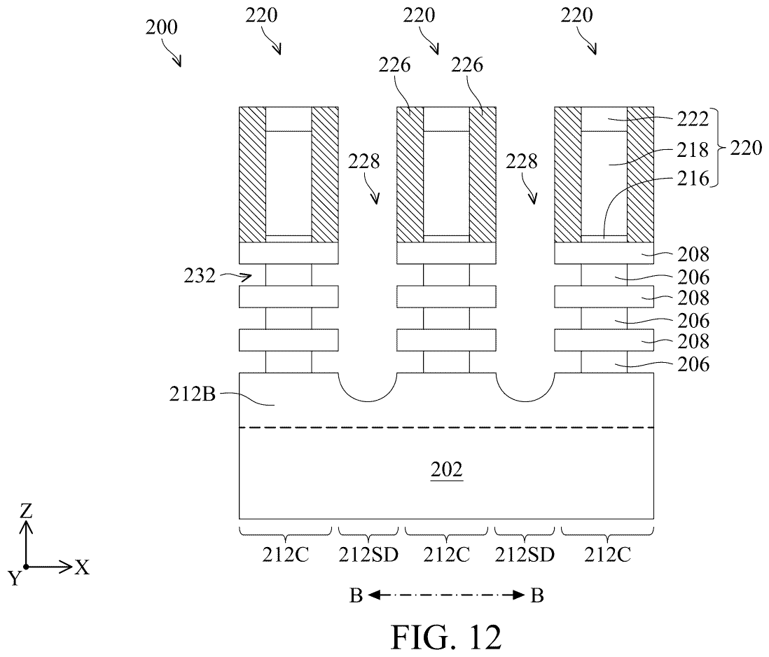

Referring to FIGS. 1 and 12, method 100 includes a block 112 where inner spacer recesses 232 are formed. The sacrificial layers 206 are selectively and partially recessed to form inner spacer recesses 232. The inner spacer recesses 232 may have a rectangular profile as illustrated. Alternatively, the inner spacer recesses 232 may have a concave profile bending away from the source/drain recesses 228. The different compositions allow the sacrificial layers 206 in the stack 204 exposed in the source/drain recesses 228 to be selectively and partially recessed to form inner spacer recesses 232 while the exposed channel layers 208 are substantially unetched. In an embodiment where the channel layers 208 consist essentially of Si and sacrificial layers 206 consist essentially of SiGe, the selective recess of the sacrificial layers 206 may include a SiGe oxidation process followed by a SiGe oxide removal. In those embodiments, the SiGe oxidation process may include use of ozone. In some embodiments, the selective recess may be a selective isotropic etching process (e.g., a selective dry etching process or a selective wet etching process), and the extent the sacrificial layers 206 are recessed is controlled by duration of the etching process. In some embodiments, the selective dry etching process may include use of one or more fluorine-based etchants, such as fluorine gas or hydrofluorocarbons. The inner spacer recesses may extend inward along the X-direction from the source/drain recesses 228. In some embodiments, the selective wet etching process may include a hydro fluoride (HF) or NH₄OH etchant.

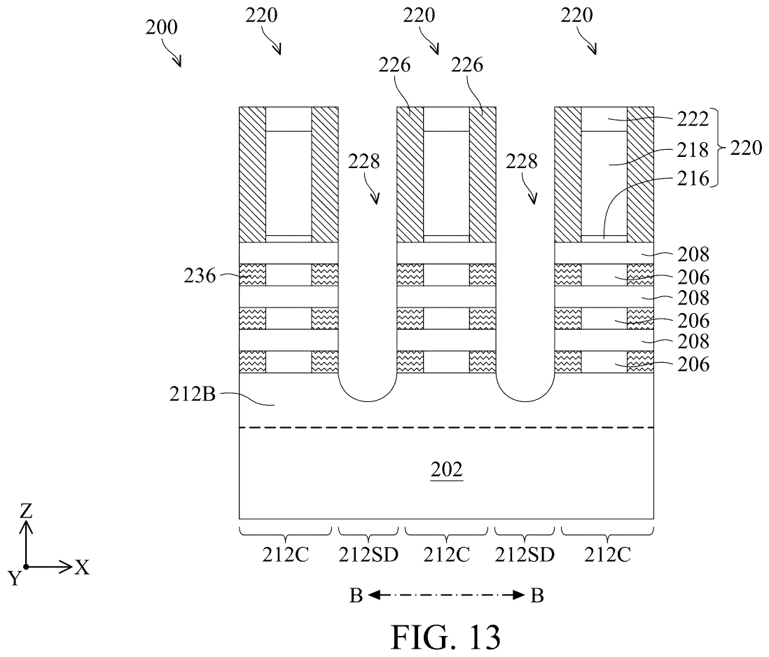

Referring to FIGS. 1 and 13, method 100 includes a block 114 where inner spacers 236 are formed in the inner spacer recesses 232. The formation of the inner spacers 236 may include the deposition of an inner spacer layer over exposed surfaces of the source/drain recesses 228, including filling the inner spacer recesses 232. In some embodiments, the inner spacer layer may include silicon carbonitride (SiCN), silicon oxycarbonitride (SiOCN), silicon nitride (SiN), silicon oxycarbide (SiOC), or silicon oxynitride (SiON). In some implementations, the inner spacer layer may be deposited using CVD or ALD. Subsequently, the inner spacer layer is etched back to form inner spacers 236 in the inner spacer recesses 232. In some embodiments, the etching back of the inner spacer layer may include use of a dry etching process, such as a reactive ion etching (RIE) process that is aided by plasma. An example dry etching process may include use of boron trichloride (BCl₃), chlorine (Cl₂), hydrogen chloride (HCl), methane (CH₄), nitrogen trifluoride (NF₃), carbon tetrafluoride (CF₄), sulfur hexafluoride (SF₆), nitrogen (N₂), or a combination thereof. In the depicted embodiment, the inner spacers 236 substantially remain under the gate spacers 226 without extending to a position directly under the dummy gate stack 220. Alternatively, the inner spacers 236 may laterally extend to a position directly under the dummy gate stack 220.

Referring to FIGS. 1 and 14-15, method 100 includes a block 116 where a source/drain feature 244 is formed over the source/drain region 212SD. While not explicitly shown, before any of the epitaxial layers are formed, method 100 may include a cleaning process to clean surfaces of the structure 200. The cleaning process may include a dry clean, a wet clean, or a combination thereof. In some examples, the wet clean may include use of a mixture of deionized (DI) water, ammonium hydroxide, and hydrogen peroxide, a mixture of DI water, hydrochloric acid, and hydrogen peroxide, SPM (a sulfuric peroxide mixture), and/or hydrofluoric acid for oxide removal. The dry clean process may include helium (He) and hydrogen (H₂) treatment.

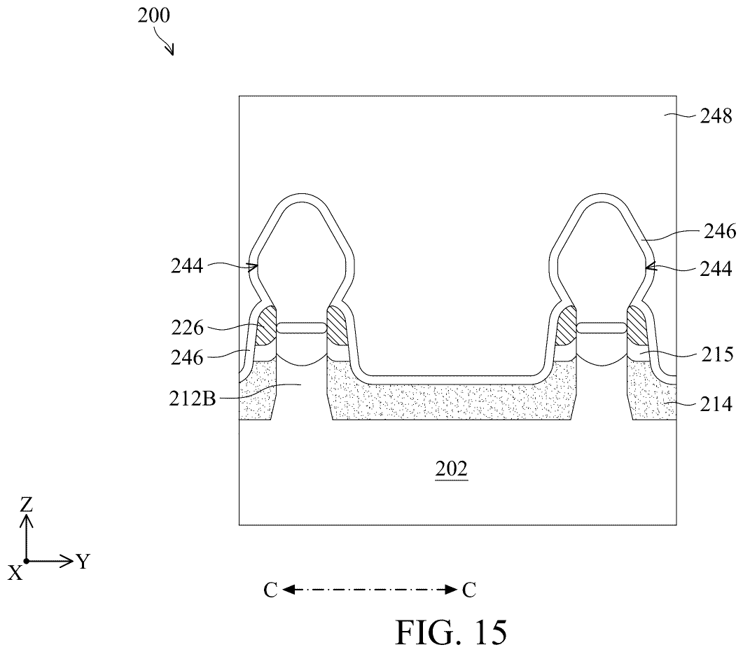

Source/drain feature(s) 244 may refer to a source or a drain, individually or collectively dependent upon the context. The source/drain features 244 are coupled to the channel regions 212C. Each of the source/drain features 244 may be epitaxially and selectively formed from exposed semiconductor surfaces by using an epitaxial process, such as vapor phase epitaxy (VPE), ultrahigh vacuum chemical vapor deposition (UHV-CVD), molecular-beam epitaxy (MBE), and/or other suitable processes. Example n-type source/drain features may include silicon, phosphorus-doped silicon, arsenic-doped silicon, antimony-doped silicon, or other suitable material and may be in-situ doped during the epitaxial process by introducing an n-type dopant, such as phosphorus, arsenic, or antimony, or ex-situ doped using a junction implant process. Example p-type source/drain features may include germanium, gallium-doped silicon germanium, boron-doped silicon germanium, or other suitable material and may be in-situ doped during the epitaxial process by introducing a p-type dopant, such as boron or gallium, or ex-situ doped using a junction implant process. In some embodiments, each of the n-type source/drain features and the p-type source/drain features may include multiple semiconductor layers (e.g., as depicted) with different doping concentrations. The n-type source/drain features and the p-type source/drain features may be formed in any suitable sequential orders. One or more annealing processes may be performed to activate the dopants in the source/drain features 244. The annealing processes may include rapid thermal annealing (RTA) and/or laser annealing processes. As illustrated in FIG. 15, in some embodiments, in the Y-Z plane each source/drain feature 244 may include a portion overhanging the isolation structure 214 and the protecting layer 215.

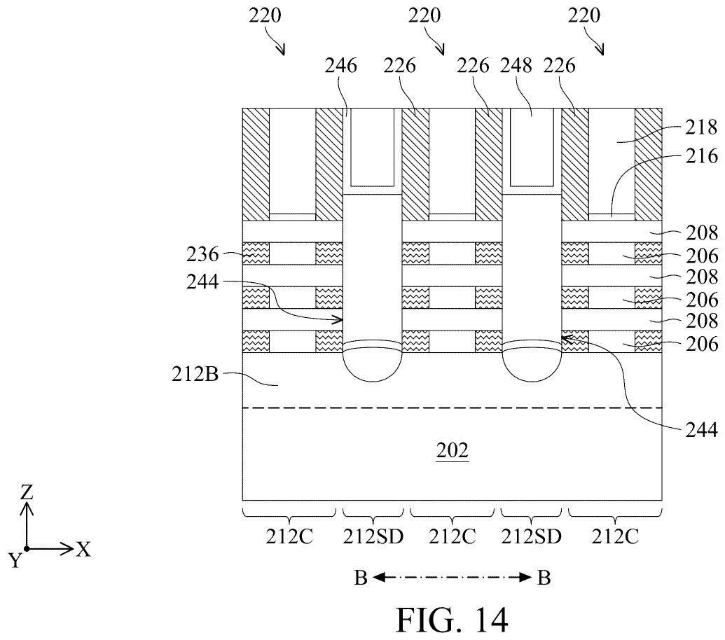

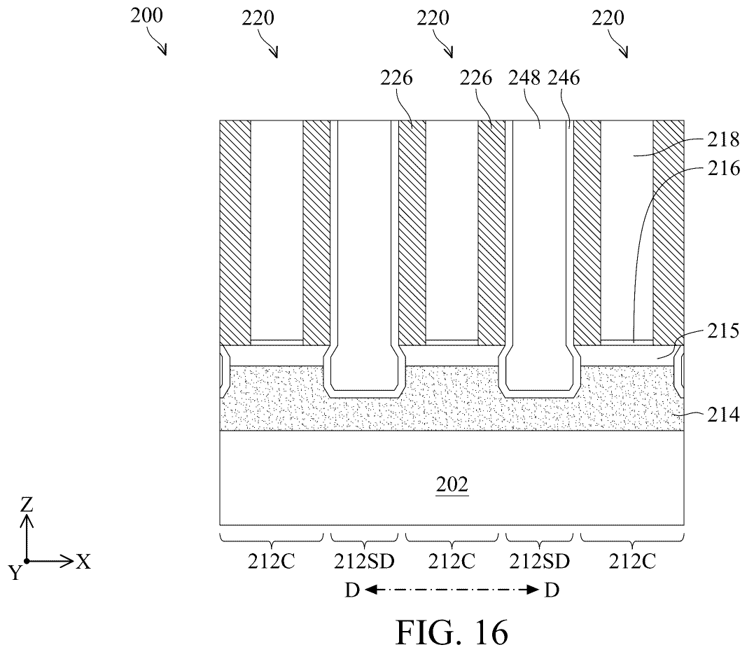

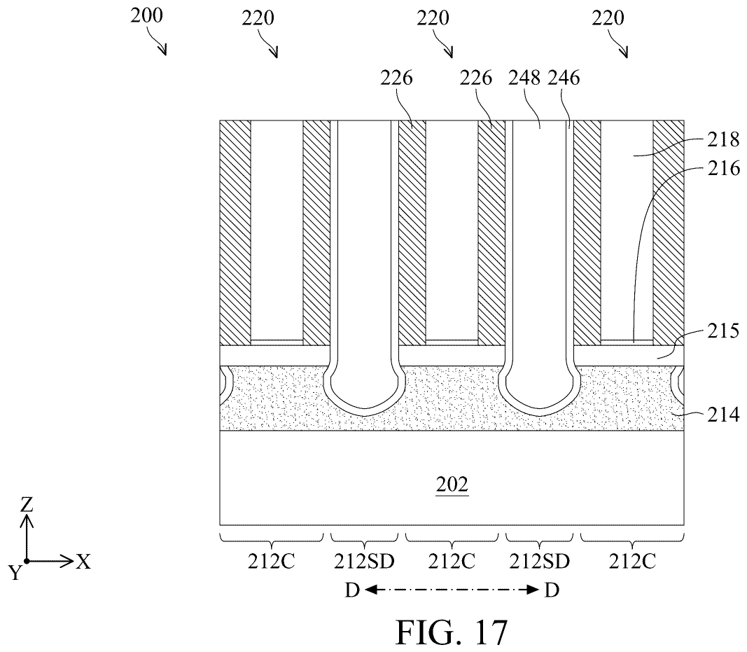

Referring to FIGS. 1 and 14-17, method 100 includes a block 118 where a contact etch stop layer (CESL) 246 and a first interlayer dielectric (ILD) layer 248 are deposited in the source/drain regions 212SD. As shown in FIGS. 14-15, the CESL 246 is deposited over the source/drain feature 244. As shown in FIG. 15, the fin spacers 226 are also covered by the CESL 246. The CESL 246 may include silicon nitride or aluminum nitride. In some implementations, the CESL 246 may be deposited using CVD or ALD. The first ILD layer 248 is then deposited over the CESL 246. In some embodiments, the first ILD layer 248 includes materials such as an oxide-based dielectric material, SiOx, SiON, SiC, tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The first ILD layer 248 may be deposited using CVD, flowable CVD (FCVD), spin-on coating, or a suitable deposition technique. As shown in FIGS. 16 and 17, which illustrate the structure 200 fabricated from embodiments represented by FIGS. 10 and 11, respectively, the CESL 246 also lines the cavity underneath the protecting layer 215. The bottom portions of the CESL 246 and first ILD layer 248 extend directly under the gate spacers 226 and are partially embedded in the isolation structure 214. After the deposition of the first ILD layer 248, the structure 200 may be planarized by a planarization process to remove the gate-top hard mask layer 222 and expose the dummy electrode layer 218. For example, the planarization process may include a chemical mechanical planarization (CMP) process. After the planarization, top surfaces of the CESL 246, the first ILD layer 248, the gate spacers 226, and the dummy electrode layer 218 are coplanar.

Referring to FIGS. 1 and 18-21, method 100 includes a block 120 where the dummy gate stacks 220 and subsequently the sacrificial layers 206 are selectively removed. The exposure of the dummy gate stack 220 at the conclusion of operations at block 118 allows the removal thereof. The removal of the dummy gate stack 220 may include one or more etching processes that are selective to the materials of the dummy gate stack 220. For example, the removal of the dummy gate stack 220 may be performed using a selective wet etch, a selective dry etch, or a combination thereof that is selective to the dummy gate stack 220. The removal of the dummy gate stacks 220 forms gate trenches 250 that expose the stack of the channel layers 208 and the sacrificial layers 206. After the removal of the dummy gate stack 220, the sacrificial layers 206 in the channel regions 212C are exposed and subsequently removed in a separate etching process. For example, a selective wet etching process or a selective dry etching process may be performed to remove the sacrificial layers 206. An example selective wet etching process may include use of diluted hydrofluoric acid (DHF) or a mixture of hydrofluoric acid (HF) and ammonium fluoride (NH₄F). An example selective dry etching process may include use of anhydrous hydrogen fluoride (HF) vapor, trifluoromethane (CHF₃), nitrogen trifluoride (NF₃), hydrogen (H₂), ammonia (NH₃), carbon tetrafluoride (CF₄), sulfur hexafluoride (SF₆), or a combination thereof. After the removal of the sacrificial layers 206, the channel layers 208 are released as channel members (also referred to as channel members 208 hereinafter).

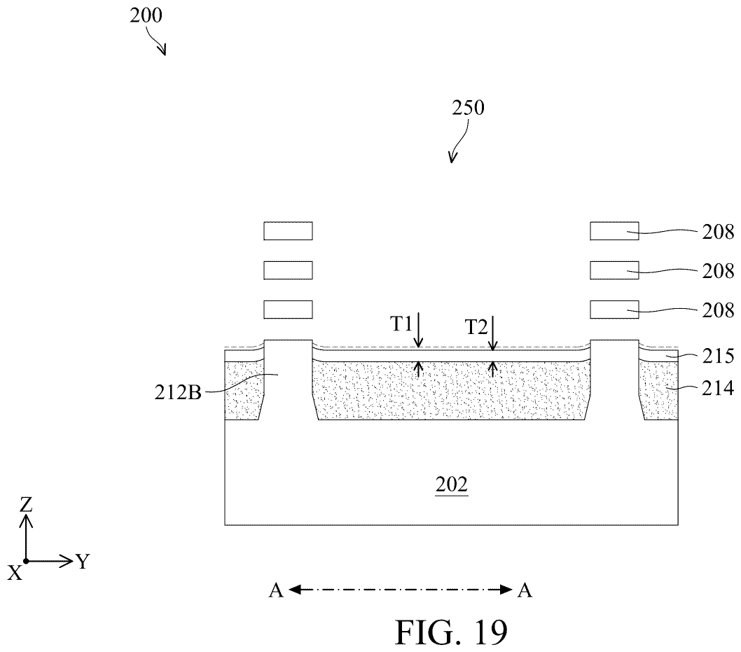

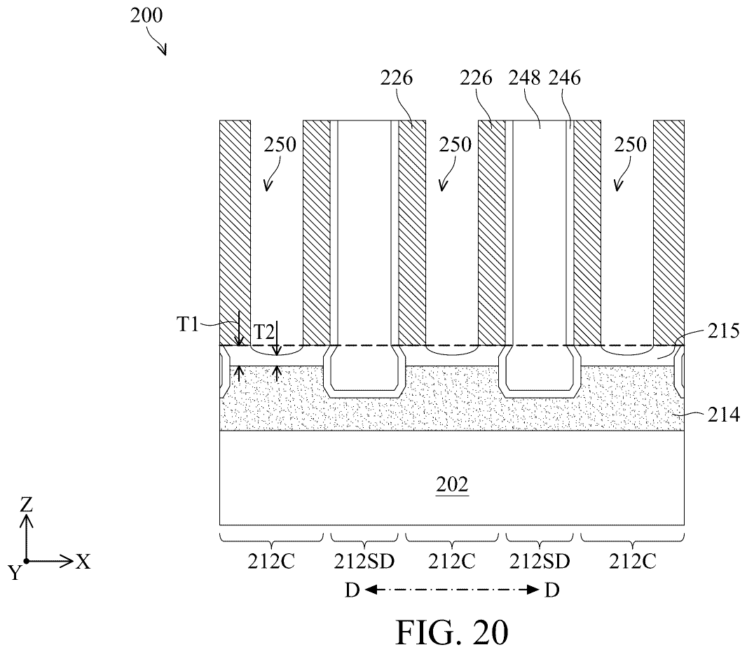

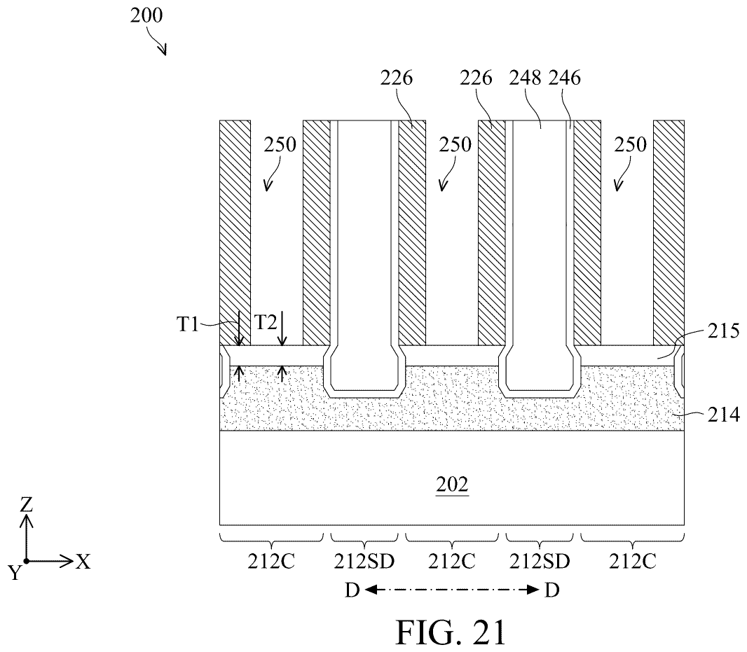

As shown in FIGS. 19-20, the etching processes may partially recess the protecting layer 215 to form ditches due to limited etching contrast, causing the bottom surface of the gate trench 250 to extend below the original top surface of the protecting layer 215 (shown in dashed lines). In some embodiments, the top surface of the protecting layer 215 in the gate trench 250 may have a concaved profile. Nevertheless, the protecting layer 215 prevents the gate trench 250 from extending through, thereby ensuring that the isolation structure 214 beneath the gate trench 250 remains intact. The protecting layer 215 may have a thickness T2 in the gate trench 250. T2 may be about 8 nm to about 50 nm. In some embodiments, a ratio of T2 to T1 is about 1:4 to about 1:1. If T2 is too small or the ratio is too small, the protecting layer 215 may be too thin to be a stop layer in the following processes. In some alternative embodiments as in FIG. 21, the protecting layer 215 remains unetched in the etching processes and T2 is the same as T1.

Referring to FIGS. 1-2 and 22-24, method 100 includes a block 122 where gate structures 260 are formed in the gate trenches 250 to wrap around each of the channel members 208. The gate structure 260 is also referred to as metal gate structure 260 due to its metal-containing layers. In the depicted embodiment, the gate structure 260 includes an interfacial layer 262 interfacing the channel members 208, a high-k dielectric layer 264 over the interfacial layer 262, and a gate electrode layer 266 over the high-k dielectric layer 264. The interfacial layer 262 and the high-k dielectric layer 264 are collectively referred to as a gate dielectric layer.

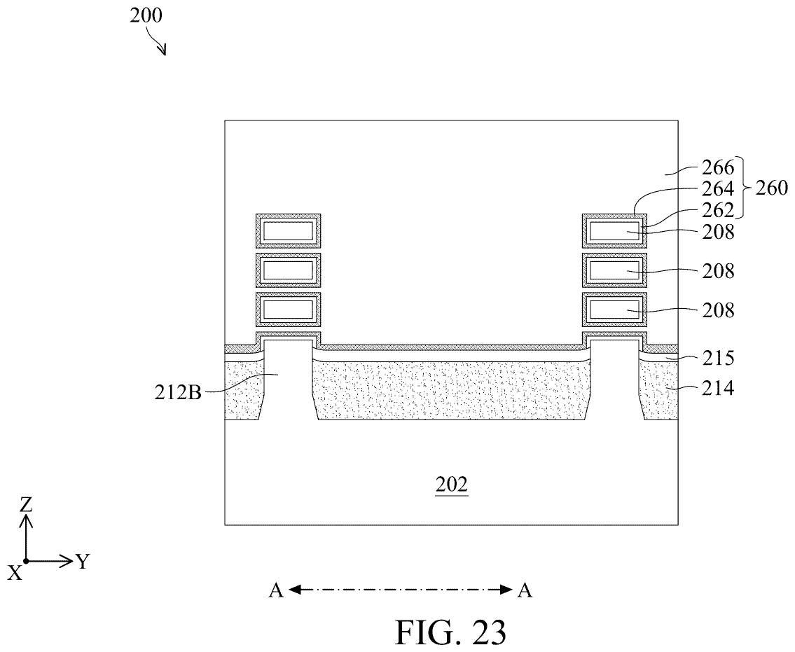

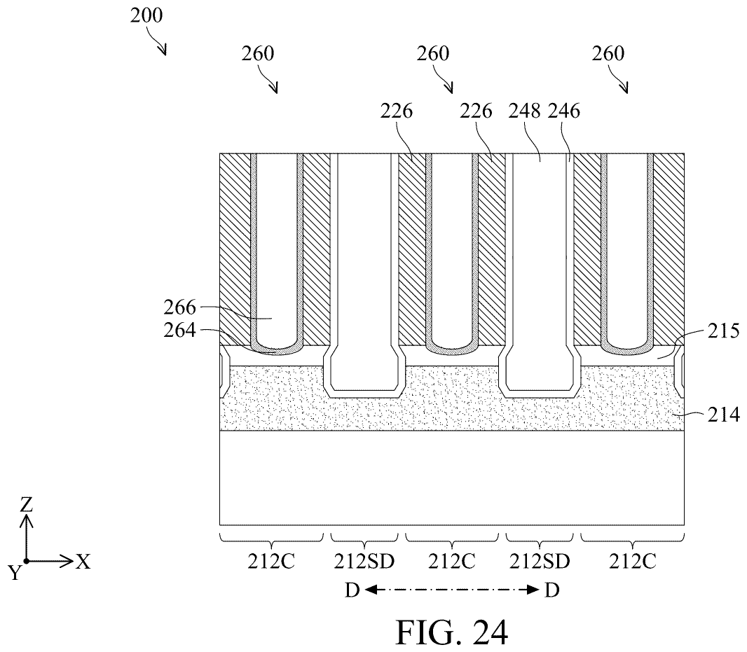

The interfacial layer 262 may include a dielectric material such as silicon oxide, hafnium silicate, or silicon oxynitride. The interfacial layer 262 may be formed by chemical oxidation, thermal oxidation, atomic layer deposition (ALD), chemical vapor deposition (CVD), and/or other suitable method. In the illustrated embodiment, the interfacial layer 262 is formed by thermal oxidating semiconductor materials exposed in the gate trenches 250. Therefore, the interfacial layer 262 is formed on semiconductor surfaces, such as the exposed surfaces of the channel members 208 and the top surface of the fin-shaped base 212B, but not on dielectric surfaces, such as sidewalls of the inner spacers 236, sidewalls of the gate spacers 226, and top surface of the isolation structure protecting layer 215 (FIGS. 23-24). The high-k dielectric layer 264 may include a high-k dielectric material, such as hafnium oxide. Alternatively, the high-k dielectric layer 264 may include other high-k dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO), combinations thereof, or other suitable material. A dielectric constant of the high-k dielectric layer 264 is greater than a dielectric contact of the gate spacers 226. The high-k dielectric layer 264 may be formed by ALD, physical vapor deposition (PVD), CVD, oxidation, and/or other suitable methods. As shown in FIGS. 23-24, the high-k dielectric layer 264 may be conformally deposited on exposed dielectric surfaces exposed in the gate trenches 250.

The gate electrode layer 266 includes a work function metal layer and a metal fill layer over the work function layer. The work function metal layer is a p-type work function metal layer in the p-type transistors or an n-type work function metal layer in the n-type transistors. The p-type work function metal layer includes a metal selected from, but not limited to, the group of titanium nitride, tantalum nitride, ruthenium, molybdenum, tungsten, platinum, or combinations thereof. The n-type work function metal layer includes a metal selected from, but not limited to, the group of titanium, aluminum, tantalum carbide, tantalum carbide nitride, tantalum silicon nitride, or combinations thereof. In some embodiments, the p-type or n-type work function metal layer includes a plurality of layers deposited by CVD, PVD, and/or other suitable process. The metal fill layer includes aluminum, tungsten, cobalt, copper, and/or other suitable materials, and is formed by CVD, PVD, plating, and/or other suitable processes.

Referring to FIGS. 1-2 and 25, method 100 includes an optional block 124 where gate isolation structures 270 are formed. The gate isolation structure 270 cuts an otherwise continuous gate structure 260 into segments and may also be referred to as cut-metal-gate (CMG) feature 270. In some embodiments, the gate isolation structures 270 provide additional isolation between an FTV (to be formed) and the gate structures 260. The gate isolation structure 270 may be a single layer structure or a multi-layer structure. For a multi-layer structure, the gate isolation structure 270 may include a dielectric liner 272 and a dielectric fill layer 274. In an exemplary process flow, forming the gate isolation structure 270 includes etching through the gate structure 260 to form a CMG trench, which may extend through the protecting layer 215 and into the isolation structure 214 for better isolation, conformally depositing the dielectric liner 272 on sidewalls and a bottom surface of the CMG trench, depositing the dielectric fill layer 274 filling the CMG trench, and performing a planarization process (e.g., CMP) to remove excess portions of the dielectric materials. In some embodiments, the dielectric fill layer 274 is an oxide (e.g., silicon oxide), and the dielectric liner 272 is free of oxygen, such as a nitride (e.g., silicon nitride or silicon carbonitride). The dielectric fill layer 274 may be deposited by ALD, CVD, PVD, or other suitable processes. The dielectric liner 272 and the dielectric fill layer 274 collectively define the gate isolation structure 270.

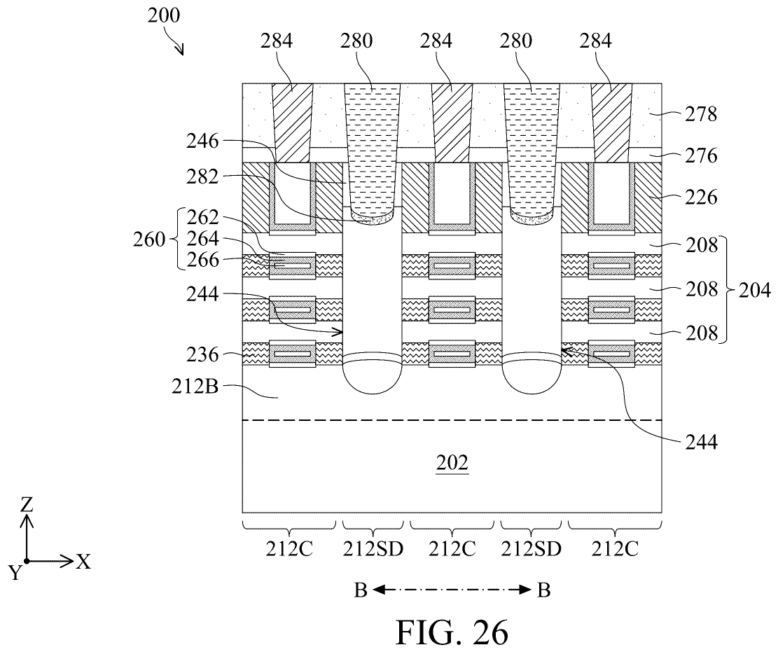

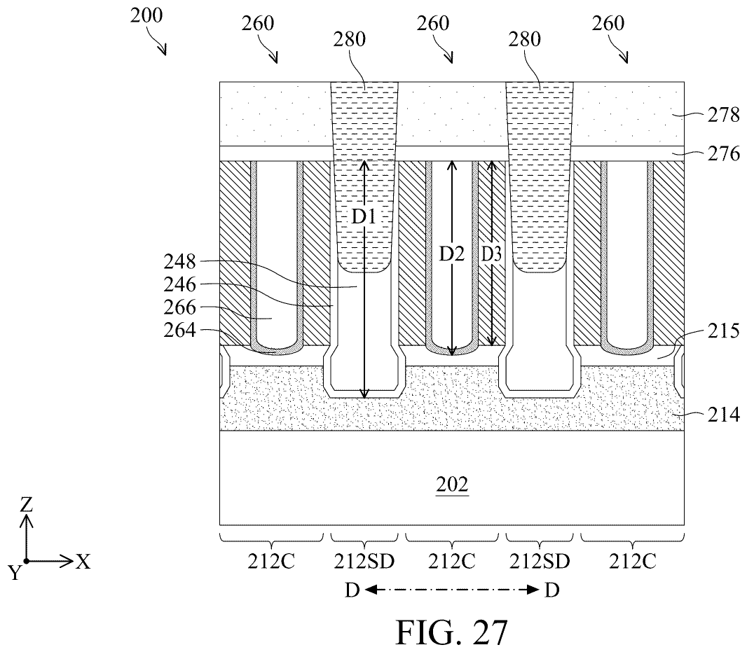

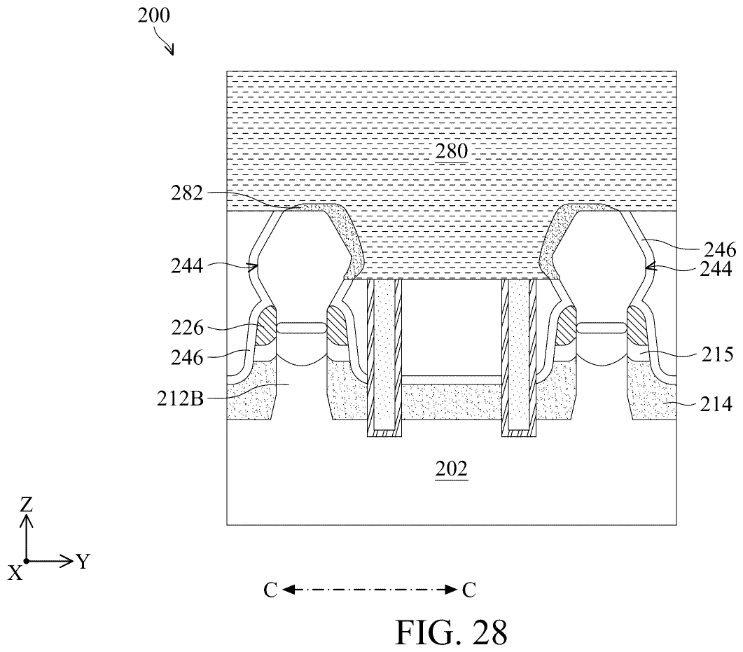

Referring to FIGS. 1-2 and 26-28, method 100 includes a block 126 where source/drain contact plugs 280 and optional silicide features 282 between the source/drain contact plugs 280 and the source/drain features 244 are formed in the source/drain regions 212SD. In an exemplary process, a capping layer 276 (also referred to as etch stop layer (ESL) 276) and a second ILD layer 278 are deposited on the structure 200. In some embodiments, a thickness of the first ILD layer 248 is greater than a thickness of the second ILD layer 278. Subsequently, contact holes are formed by etching through the second ILD layer 278, the capping layer 276, the first ILD layer 248, and the CESL 246. The etching process may be a self-aligned process such that the portion of the first ILD layer 248 above the source/drain feature 244 is removed using the vertical sidewalls of the CESL 246 as an etch stop layer (e.g., as in FIGS. 26-27). An upper portion of the source/drain feature 244 may optionally be etched to have a concave shape as a bottom of the contact hole as in FIG. 26. The silicide features 282 are formed at the bottom of the contact holes. The silicide features 282 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds. Subsequently, source/drain contact plugs 280 are formed on the silicide features 282. Each source/drain contact plug 280 may include a conductive barrier layer and a bulk metal layer. The conductive barrier layer may include titanium (Ti), tantalum (Ta), tungsten (W), cobalt (Co), ruthenium (Ru), or a conductive nitride such as titanium nitride (TiN), titanium aluminum nitride (TiAlN), tungsten nitride (WN), tantalum nitride (TaN), or combinations thereof, and may be formed by CVD, PVD, ALD, and/or other suitable processes. The bulk metal layer may include tungsten (W), cobalt (Co), molybdenum (Mo), ruthenium (Ru), nickel (Ni), copper (Cu), or other metals, and may be formed by CVD, PVD, ALD, plating, or other suitable processes. An electrical conductivity of the silicide feature 282 is between an electrical conductivity of the source/drain feature 244 and an electrical conductivity of the source/drain contact plug 280, and the electrical conductivity of the source/drain contact plug 280 is greater than the electrical conductivity of the source/drain feature 244. The silicide feature 282 and the source/drain contact plug 280 may be collectively referred to as the source/drain contact. As shown in FIG. 27, in the D-D cross-sectional view the source/drain contact plugs 280 extends further down than in the B-B cross-sectional view and directly lands on the bottom portion of the first ILD layer 248 with no silicide features 282 therebetween. Referring to FIGS. 2 and 28, in some embodiments, the source/drain contact plug 280 extends lengthwise along the Y-direction. The source/drain contact plug 280 may be disposed over and connected to one or more source/drain features 244.

In some embodiments, referring to FIGS. 2 and 26, gate vias 284 are formed similarly to the source/drain contact plugs 280 over and electrically connected to the gate structures 260. The number, position, and dimensions of the source/drain contact plugs 280 and the gate vias 284 in FIG. 2 are for examples only and do not limit the scope of the disclosure.

Referring to FIG. 27, the source/drain recess 228 (as in FIGS. 10 and 11) is now filled with the CESL 246, the first ILD layer 248, and a portion of the source/drain contact plug 280. The source/drain recess 228 has a depth D1 measured from a level of a top surface of the gate structure 260 as depicted. The gate structure 260 may have a height D2 as depicted. In some embodiments, a ratio of D2 to D1 is about 0.6 to about 0.8. If the ratio is too small (e.g., less than about 0.6), D1 may be too large, the CESL 246 and the first ILD layer 248 may penetrate too much into the isolation structure 214, which indicates too much etching in recessing the source/drain recesses 228 and may impact the performance of the structure 200. If the ratio is too large (e.g., greater than about 0.8), the protecting layer 215 may be penetrated through by the gate structure 260 or may be too thin to be a stop layer in the following processes. The gate spacer 226 may have a height D3. In some embodiments, D2 is greater than D3. In some other embodiments where the protecting layer 215 remains unetched at block 120 (e.g., as shown in FIG. 21), D2 is the same as D3.

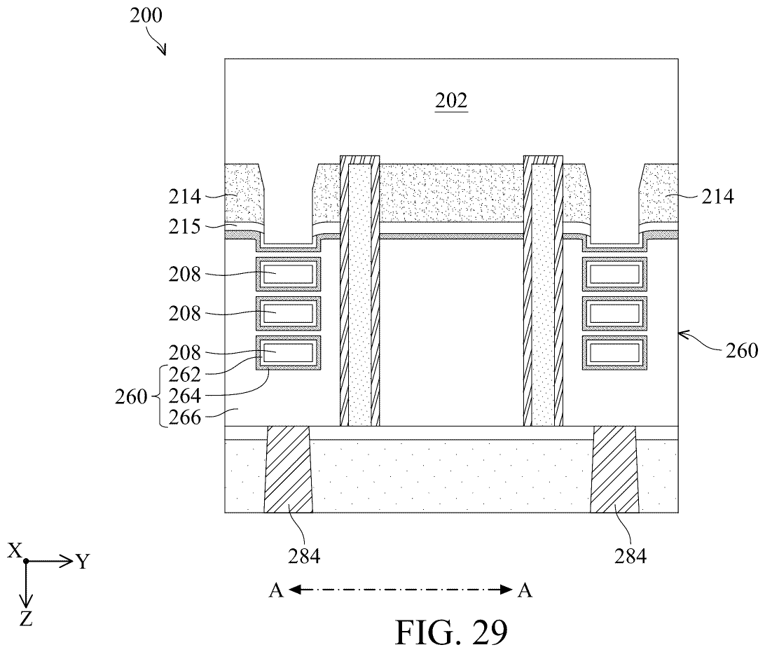

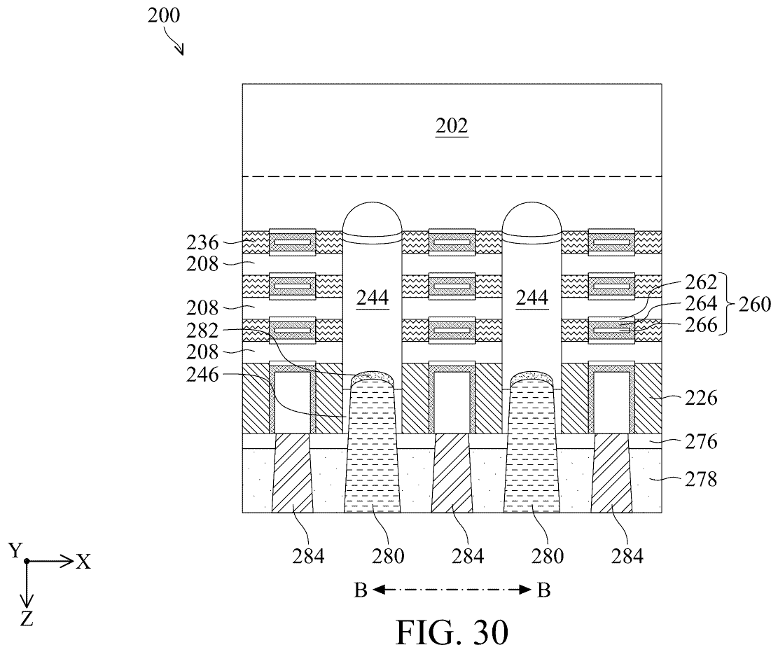

Referring to FIGS. 29-30, the structure 200 may be flipped upside down. This makes the structure 200 accessible from the backside of the structure 200 for further processing. The structure 200 may be placed on and attached to a carrier (not depicted) using any suitable attaching processes, such as direct bonding, hybrid bonding, using adhesive, or other bonding methods. Operations herein may further include alignment, annealing, and/or other processes. The carrier may be a silicon wafer in some embodiments.

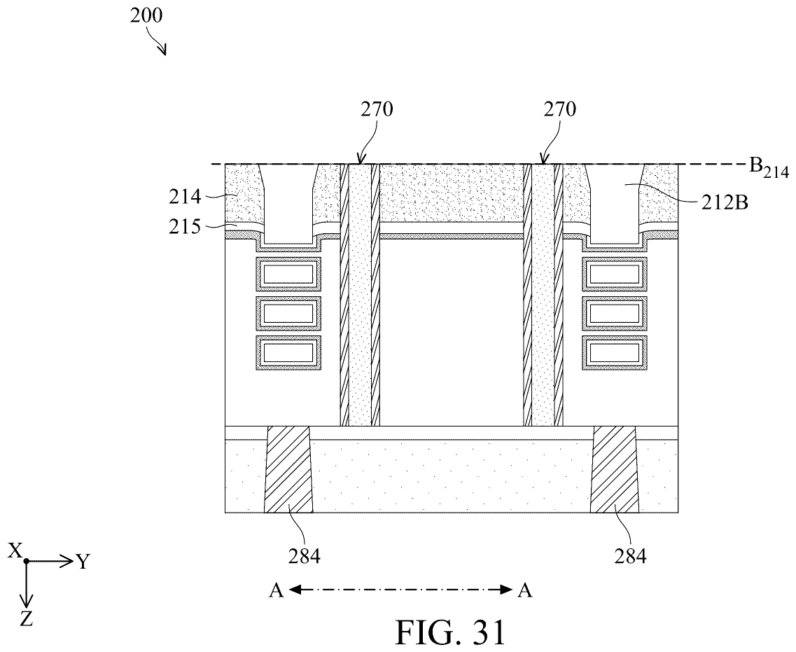

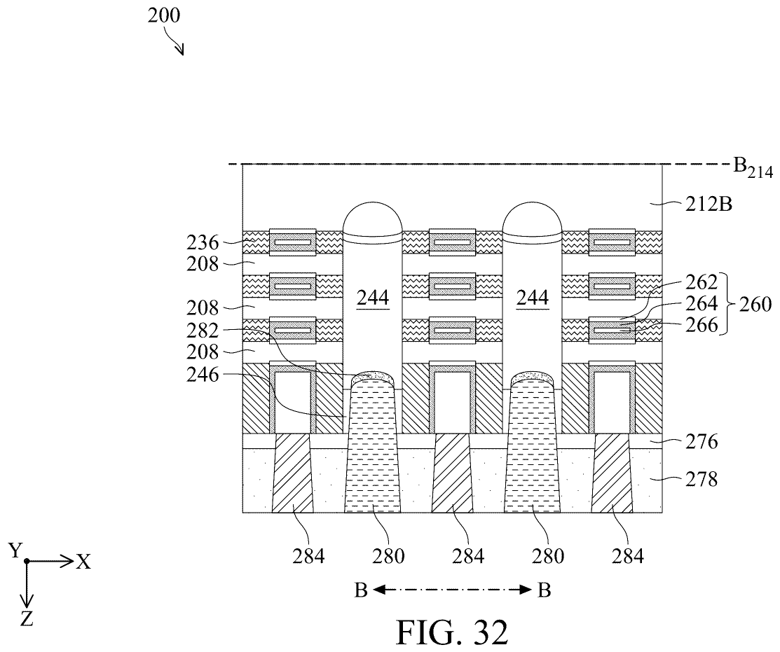

Referring to FIGS. 1 and 31-33, the method 100 includes a block 128 where the structure 200 is thinned down from the backside. In some embodiments, the thinning process may involve mechanical grinding and/or chemical thinning. Initially, a substantial amount of substrate material is removed from the substrate 202 through mechanical grinding. Subsequently, a chemical thinning process is employed, during which an etching chemical is applied to the backside of the substrate 202 for further thinning. In the depicted embodiment, the thinning is performed until the isolation structure 214 is exposed. In such embodiments, the thinning process utilizes the isolation structure 214 as a thinning stop layer, ensuring the process halts at the bottom surface of the isolation structure 214 (e.g., at the level B₂₁₄). In the illustrated embodiment, once the isolation structure 214 is exposed, additional features, such as the fin-shaped base 212B (FIGS. 31-32), the gate isolation structure 270 (FIG. 31), are also exposed on the backside of the structure 200. In some other embodiments, the thinning is performed until the protecting layer 215 is exposed. In such embodiments, the thinning process utilizes the protecting layer 215 as a thinning stop layer, ensuring the process halts at the bottom surface of the protecting layer 215. In some embodiments, the thinning is performed such that a portion of the isolation structure 214 is removed, while a portion of the isolation structure remains, and the protecting layer 215 is not exposed.

Referring to FIGS. 1 and 34-35, the method 100 includes a block 130 where backside dielectric layers are formed on the backside of the structure 200. The backside dielectric layers may include a backside etch stop layer (ESL) 286 and a backside ILD layer 288. Compositions of the backside ESL 286 and the backside ILD layer 288 and methods of forming same may be similar to those of the capping layer 276 and the second ILD layer 278.

Referring to FIGS. 1 and 36-38, the method 100 includes a block 132 where an FTV opening 290 is formed from the backside of the structure 200 to expose the protecting layer 215 and the source/drain contact plugs 280.

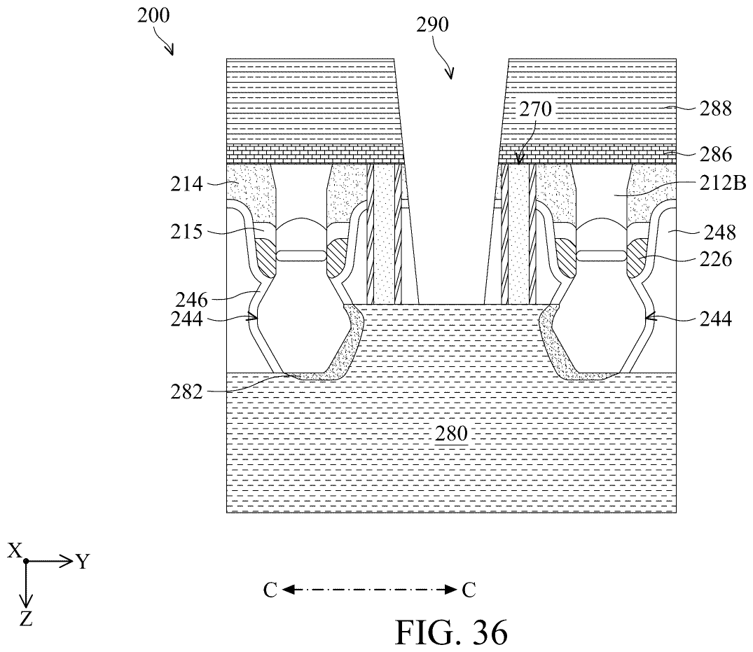

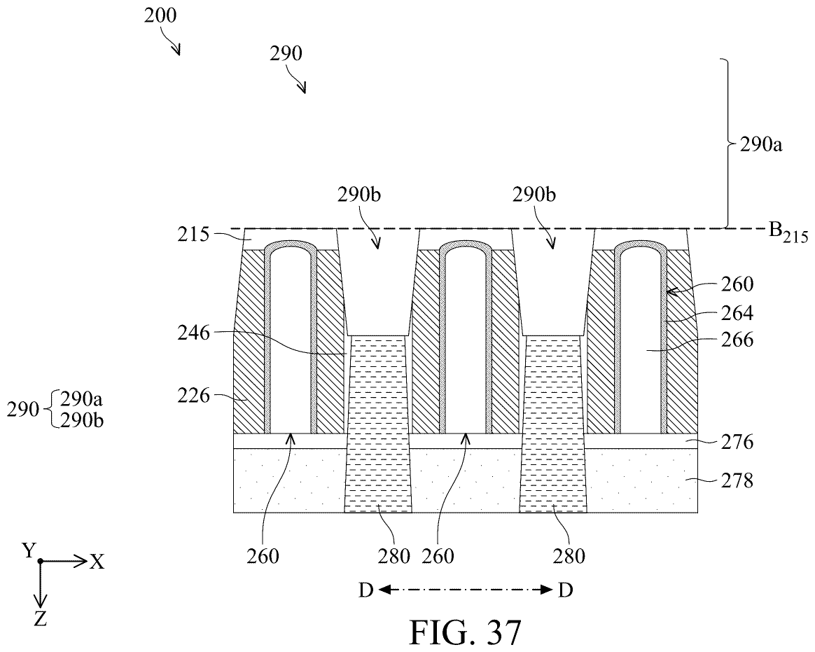

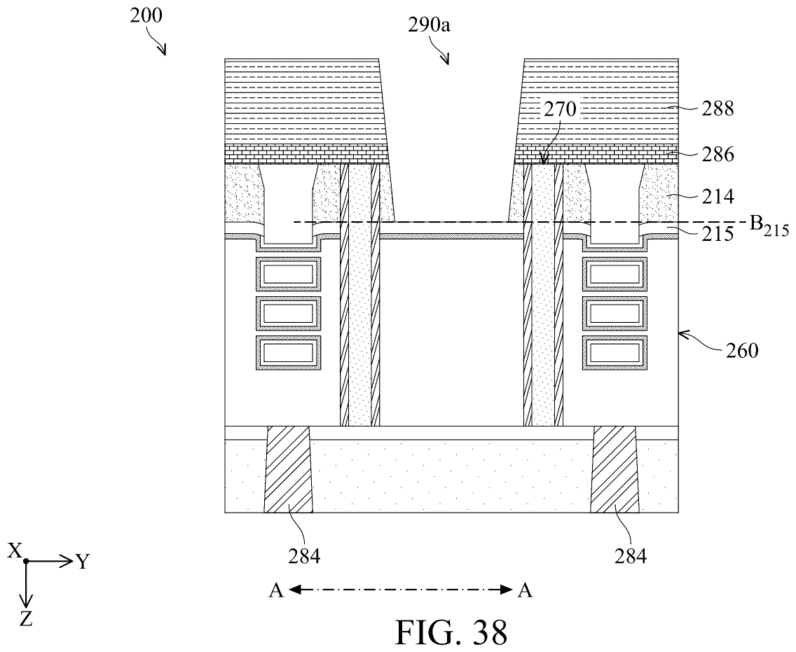

As shown in FIGS. 36 and 38, the FTV opening 290 is intended to penetrate through the backside ILD layer 288, the backside ESL 286, the isolation structure 214, the CESL 246, and the first ILD layer 248 to expose bottom surfaces of the source/drain contact plugs 280 and the bottom surfaces of the protecting layers 215. As shown in FIG. 37, the FTV opening 290 may include a first portion opening 290a below a level B₂₁₅ of the bottom surface of the protecting layers 215 and second portion opening(s) 290b between opposing gate spacers 226 and protecting layers 215.

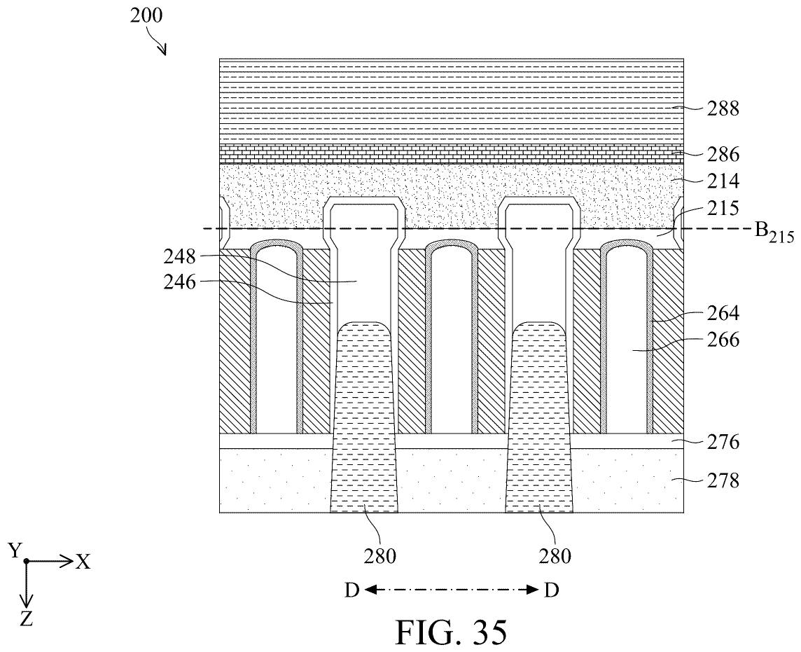

Photolithography and etching processes may be used to form the FTV opening 290. In an example process, a patterned mask (not explicitly depicted) is formed on the backside ILD layer 288 and then a first etch process is performed to form the first portion opening 290a using the patterned mask as an etch mask. The first etch process may include any suitable processes (e.g., a dry etch process, a wet etch process, or a combination thereof) using any suitable etchant. An example dry etch process may implement an oxygen-containing gas, a fluorine-containing gas (e.g., CF₄, SF₆, CH₂F₂, CHF₃, C₄F₈, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. The first etch process may use the protecting layers 215 as a stop layer. Upon completion of the first etch process, the bottom surfaces of the protecting layers 215 are exposed, and the first ILD layer 248 (shown in FIG. 35) between the level B₂₁₅ and the source/drain contact plugs 280 is exposed. A second etch process may be performed to form the second portion opening 290b. As described above, the first ILD layer 248 may include an oxide-based dielectric material and the protecting layer 215 may include a nitride-based material. The second etch process may be configured to etch the oxide-based dielectric material (e.g., silicon oxide) faster than it etches silicon or the nitride-based material. In some embodiments, the second etching process uses the protecting layers 215 as an etch mask. In some embodiments, the second etch process may include a dry etch process that uses a fluorine-containing gas (e.g., carbon tetrafluoride (CF₄), octafluorocyclobutane (C₄F₈), nitrogen trifluoride (NF₃), chlorine trifluoride (ClF₃), or sulfur hexafluoride (SF₆)), a chlorine-containing gas (e.g., chlorine (Cl₂)), oxygen (O₂), or hydrogen (H₂). In some embodiments, a portion of the CESL 246 and the gate spacers 226 are also etched in the second etch process. The FTV opening 290 may have tapered sidewalls from the etching processes as in FIGS. 36-38, such that widths of the first portion opening 290a and widths of the second portion openings 290B gradually decrease from backside to frontside (e.g., the positive Z-direction). By having the protecting layer 215, the bottom surfaces of the gate structures 260 are controlled to be above the level B₂₁₅, and the first portion opening 290a stops at the level B₂₁₅, thus exposing the gate structure 260 is avoided in the etching processes of forming the FTV opening 290.

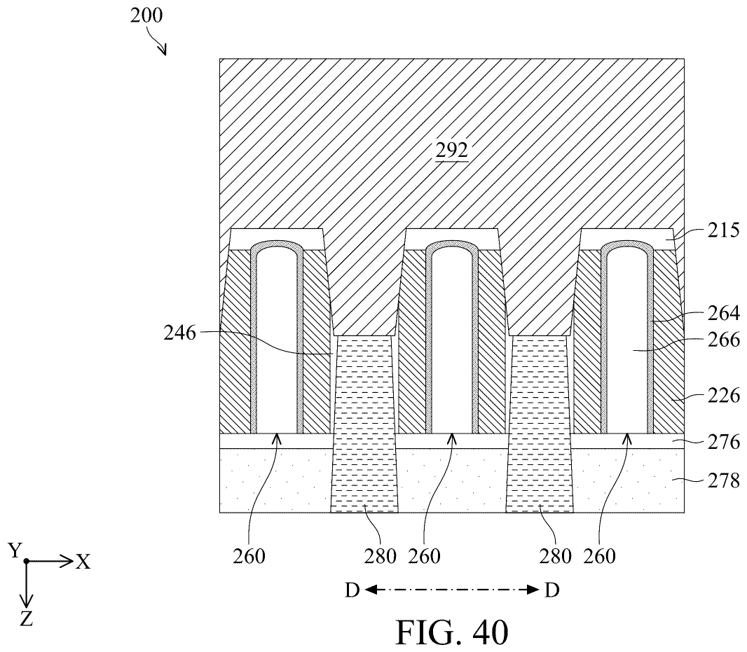

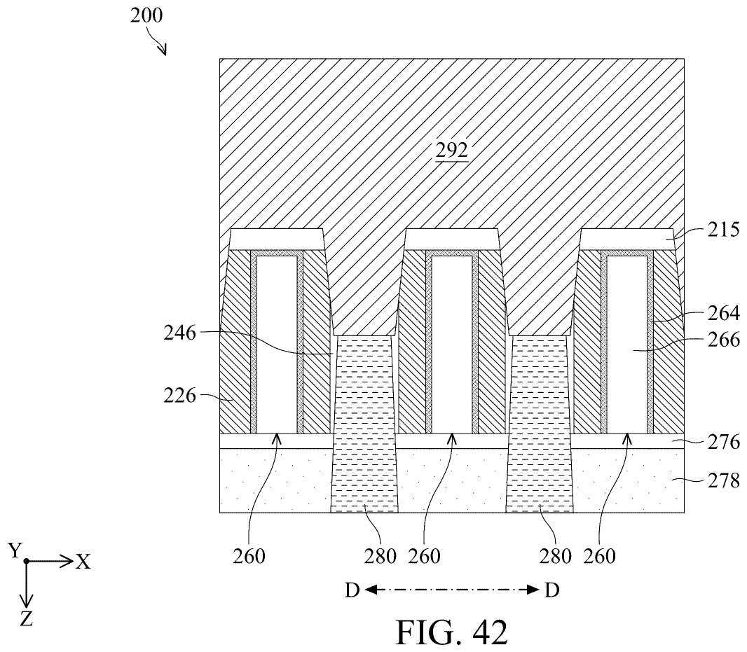

Referring to FIGS. 1-2 and 39-41, the method 100 includes a block 134 where an FTV 292 is formed in the FTV opening 290. In some embodiments, the FTV 292 may include a metal, such as cobalt (Co), nickel (Ni), ruthenium (Ru), tungsten (W), copper (Cu), or a combination thereof. In some embodiments, the FTV 292 may be formed by depositing the foregoing metal to fill in the FTV opening 290 by physical vapor deposition (PVD), metal organic CVD (MOCVD), electroplating, or electroless plating. After the deposition of the metal fill, a planarization process, such as a chemical mechanical polishing (CMP), is performed to remove excess metal over the backside ILD layer 288 to form the FTV 292. The FTV 292 lands on and electrically connects the source/drain contact plugs 280. The protecting layer 215 thus prevents the FTV 292 from directly contacting the gate structure 260, which increases the leak window between the FTV 292 and the gate structures 260. The leak window between the FTV 292 and the gate structures 260 is defined as the capability to prevent leakage between the metal gates 260 and the FTV 292. Referring to FIG. 40, the gate spacers 226 and the CESL 246 may also isolate the FTV 292 and the gate structure 260. FIG. 42 illustrates an alternative view of FIG. 40 and the structure 200 in FIG. 42 may be fabricated from the structure 200 in the embodiments represented by FIG. 21.

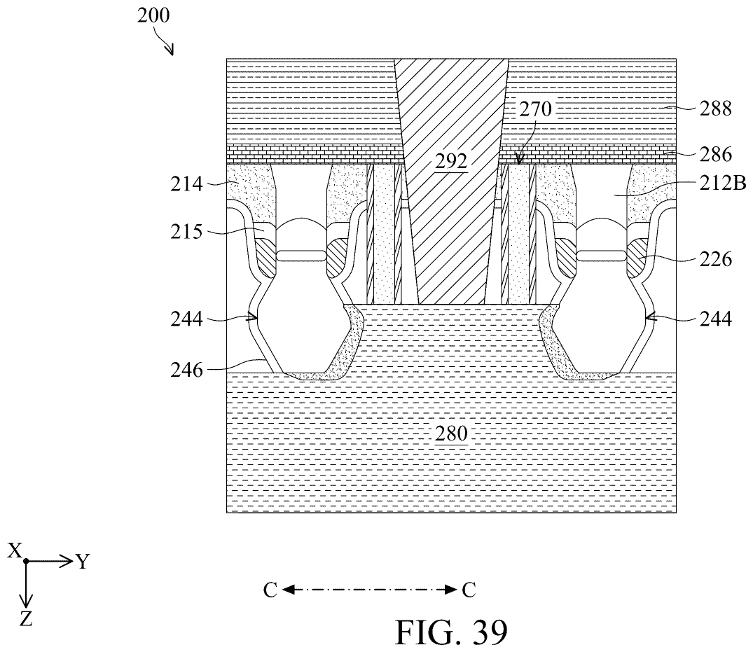

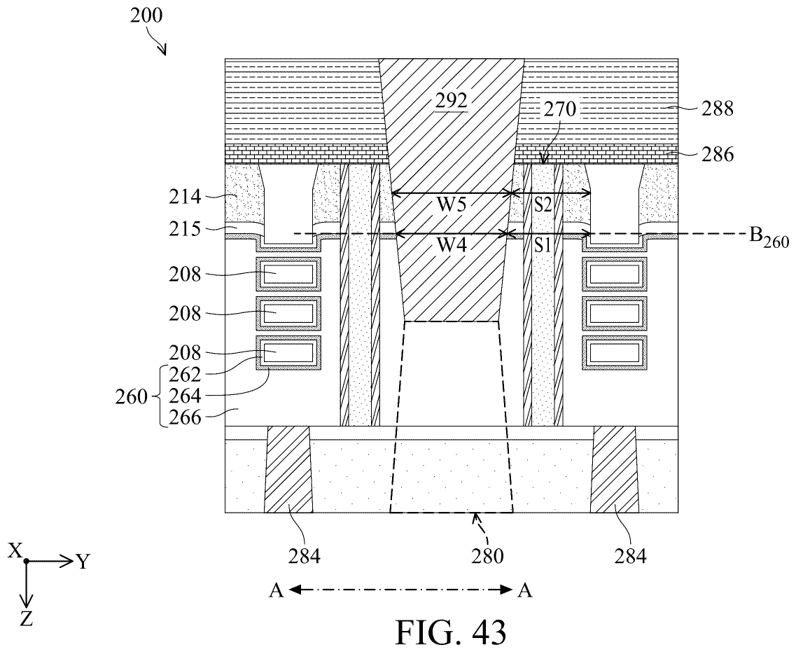

Referring to FIG. 43, the FTV 292 in the C-C cross-sectional view as in FIG. 39 is projected in this A-A cross-sectional view. The source/drain contact plug 280 shown as a dashed trapezoid in FIG. 43 is a schematic projection for simplicity and showing its connection to the FTV 292, it is understood that the shape of the source/drain contact plug 280 as in FIG. 39 is different. A width W4 of the FTV 292 in the Y-direction at a level B₂₆₀ of a bottom surface of the gate structure 260 (e.g., an interface between the gate structure 260 and the protecting layer 215) may be referred to as a critical dimension (or a gate structure correlated critical dimension) of the FTV 292. The critical dimension of the FTV 292 may affect leak window between the FTV 292 and the gate structures 260. Because of the tapered sidewalls of the FTV 292, widths of the FTV 292 in the Y-direction decrease along the positive Z-direction. For example, the width W4 at the level B₂₆₀ is less than a width W5 below the level B₂₆₀. Accordingly, a distance between the FTV 292 and the fin-shaped base 212B in the Y-direction increases along the positive Z-direction. For example, a distance S1 at the level B₂₆₀ is greater than a distance S2 below the level B₂₆₀. By having the protecting layer 215, control of the level B₂₆₀ is improved (e.g., the level B₂₆₀ is kept above the isolation structure 214), thus the critical dimension of the FTV 292 is reduced, the distance between the FTV 292 and the fin-shaped base 212B in the Y-direction is increased, and the leak window between the FTV 292 and the gate structures 260 is increased.

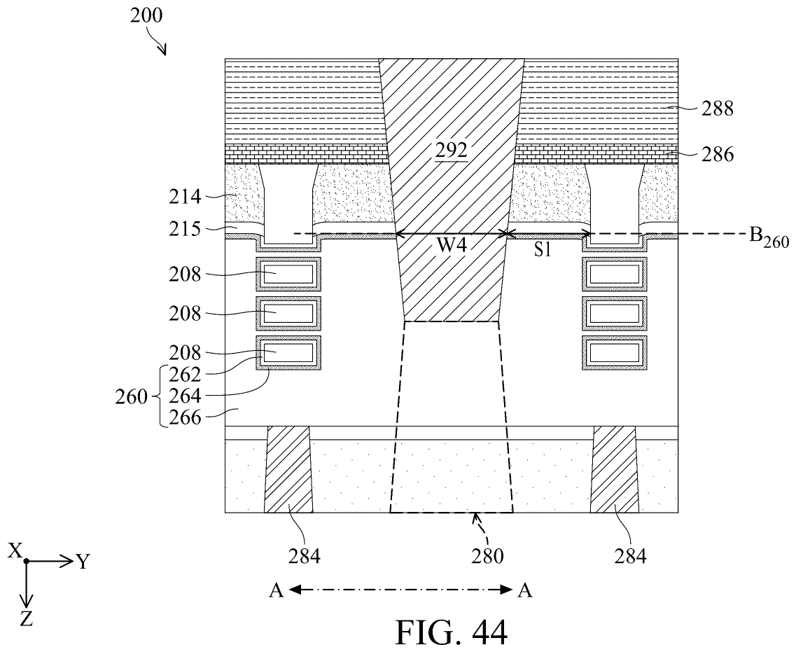

In some embodiments, as the leak window between the FTV 292 and the gate structures 260 is increased, at least one of the gate isolation structures 270 in FIG. 43 may be omitted without causing leakage between the FTV 292 and the gate structures 260. FIG. 44 illustrates an example structure 200 when both of the gate isolation structures 270 in FIG. 43 are omitted. This may reduce the footprint of the structure 200 and reduce cost and time associated therewith.

The structure 200 may undergo additional processes to form various features and regions known in the art. For example, additional processing may form additional frontside and/or backside interlayer dielectric (ILD) layer(s), frontside and/or backside contacts/vias/lines and frontside and/or backside multilayers interconnect features (e.g., metal layers and interlayer dielectrics), configured to connect the various features to form a functional circuit that may include one or more devices including the semiconductor device 200. The additional frontside features may be formed before flipping the structure 200. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. In some embodiments, a backside metal line (e.g., a backside power rail) may be formed below and be connected to the FTV 292.

Although FIGS. 3-42 illustrate GAA transistors, other examples of semiconductor devices (e.g., FinFETs (fin field-effect transistors), other multigate devices) may benefit from aspects of the present disclosure.

Although not intended to be limiting, one or more embodiments of the present disclosure provide many benefits to a semiconductor structure. For example, the protection layer may be used as a stop layer in forming the FTV opening and may isolate the FTV from the gate structure. In addition, by having the protection layer, the gate trench may be controlled not to penetrate into the isolation structure, thus the bottom surface of the gate structure may be elevated, the critical dimension of the FTV is reduced, and the leak window between the FTV and the gate structure is increased. Thus, the overall performance of the semiconductor device may be improved. Further, the gate isolation structure(s) for isolating the FTV and the gate structure may be omitted, which reduces the footprint of the structure and reduce cost and time associated therewith.

In one exemplary aspect, the present disclosure is directed to a method. The method includes forming a stack on a substrate. The stack includes a plurality of first semiconductor layers interleaved by a plurality of second semiconductor layers. The method further includes patterning the stack and a top portion of the substrate to form a first active region and a second active region protruding from a bottom portion of the substrate and extending lengthwise in a direction. The first active region includes a first fin base and a first stack of semiconductor layers over the first fin base, the second active region includes a second fin base and a second stack of semiconductor layers over the second fin base. The method further includes forming an isolation structure between the first active region and the second active region, depositing a protecting layer on the isolation structure, forming a dummy gate stack across the first active region and the second active region, the dummy gate stack interfacing a top surface of the protecting layer, depositing gate spacers on sidewalls of the dummy gate stack, recessing the first and second active regions outside of the dummy gate stack and the gate spacers to form a first trench and a second trench, respectively, forming a first source/drain feature in the first trench and a second source/drain feature in the second trench, removing the dummy gate stack to form a gate trench, the gate trench exposing the protecting layer, removing the second semiconductor layers from the gate trench, depositing a gate structure in the gate trench, the gate structure interfacing the top surface of the protecting layer, forming a source/drain contact disposed over and connected to the first source/drain feature, thinning the substrate to expose a back side of the isolation structure, forming a backside dielectric structure on the back side of the isolation structure, forming a backside opening through the backside dielectric structure and exposing a bottom surface of the protecting layer, a bottom surface of the source/drain contact, and sidewalls of the gate spacers, and forming a conductive feature in the backside opening and electrically connected to the source/drain contact. A portion of the first source/drain feature overhangs the isolation structure, a portion of the second source/drain feature overhangs the isolation structure.

In some embodiments, the isolation structure interfaces a sidewall of the first fin base and a sidewall of the second fin base. In some embodiments, the source/drain contact is disposed over and connected to the second source/drain feature. In some embodiments, the method further includes forming a first dielectric layer along a sidewall of the first fin base, and forming a second dielectric layer along a sidewall of the first dielectric layer. The first dielectric layer and the second dielectric layer are between the isolation structure and the first fin base, the first dielectric layer includes less than about 10% nitrogen, and the second dielectric layer includes an oxide. In some embodiments, removing the dummy gate stack further removes a top portion of the protecting layer and a bottom portion of the protecting layer remains. In some embodiments, the first trench and the second trench extend through the protecting layer and expose the isolation structure. In some embodiments, a top portion of the first trench adjacent to the gate spacers has a first width along the direction, a bottom portion of the first trench spanning between sidewalls of the isolation structure has a second width along the direction, the second width greater than the first width. In some embodiments, a middle portion of the first trench adjacent to the protecting layer and between the top portion and the bottom portion has a third width along the direction, the third width less than the second width. In some embodiments, thinning the substrate removes at least a bottom portion of the isolation structure.

In another exemplary aspect, the present disclosure is directed to a method. The method includes providing a structure including a substrate and a fin-shaped structure protruding from the substrate, forming an isolation structure over the substrate and adjacent to a sidewall of the fin-shaped structure, forming a protecting layer on the isolation structure, epitaxially growing a source/drain feature on a source/drain region of the fin-shaped structure, depositing a contact etch stop layer (CESL) over the source/drain feature, depositing a first interlayer dielectric (ILD) layer over the CESL, depositing a capping layer over a top surface of the CESL and a top surface of the first ILD layer, depositing a second ILD layer over the capping layer, forming a source/drain contact plug disposed in the first ILD layer to electrically couple to the source/drain feature, forming a metal silicide layer disposed between the source/drain feature and the source/drain contact plug, thinning down the substrate from a bottom of the structure until the isolation structure is exposed, forming an opening exposing a bottom surface of the source/drain contact plug and a bottom surface of the protecting layer, and depositing a backside conductive feature in the opening. An electrical conductivity of the metal silicide layer is between an electrical conductivity of the source/drain feature and an electrical conductivity of the source/drain contact plug, the metal silicide layer includes a curved profile.

In some embodiments, the fin-shaped structure includes a fin base and a stack of channel layers and sacrificial layers, and the method further includes forming a dummy gate structure over a channel region of the fin-shaped structure, after depositing the first ILD layer, removing the dummy gate structure and the sacrificial layers to form a gate trench, and forming a gate structure in the gate trench and wrapping around the stack of channel layers, the gate structure is disposed on a top surface of the protecting layer opposite to the bottom surface of the protecting layer. In some embodiments, the fin-shaped structure extends lengthwise along a direction, and a portion of the backside conductive feature is spaced apart from the gate structure by a gate spacer along the direction. In some embodiments, removing the dummy gate structure and the sacrificial layers further removes a top portion of the protecting layer in the gate trench, such that the top surface of the protecting layer has a concaved profile. In some embodiments, epitaxially growing the source/drain feature includes forming a source/drain recess in the source/drain region of the fin-shaped structure, and epitaxially growing the source/drain feature in the source/drain recess, forming the source/drain recess removes a portion of the protecting layer to expose the isolation structure. In some embodiments, forming the opening removes portions of the isolation structure, the CESL, and the first ILD layer. In some embodiments, before thinning down the substrate, the ILD layer includes a bottom portion embedded in the isolation structure and a top portion above the bottom portion, the bottom portion is wider than the top portion along a lengthwise extending direction of the fin-shaped structure.

In yet another exemplary aspect, the present disclosure is directed to a semiconductor structure. The semiconductor structure includes one or more nanostructures disposed over a semiconductor fin base, an isolation structure disposed on a side of the semiconductor fin base, a protecting layer disposed on the isolation structure and below a bottommost surface of the one or more nanostructures, first and second source/drain features connected by the one or more nanostructures, a gate structure disposed over the one or more nanostructures and interfacing a top surface of the protecting layer, a gate spacer extending along a sidewall of the gate structure and interfacing the top surface of the protecting layer, a source/drain contact disposed over and electrically coupled to the first source/drain feature, and a backside conductive feature landing on a bottom surface of the protecting layer and a bottom surface of the source/drain contact. An electrical conductivity of the source/drain contact is greater than an electrical conductivity of the first source/drain feature, the backside conductive feature is electrically isolated from the gate structure by the gate spacer and the protecting layer.

In some embodiments, the semiconductor structure further includes a low nitrogen dielectric layer disposed on a sidewall of the semiconductor fin base, and an oxide layer and disposed on a sidewall of the low nitrogen dielectric layer. The isolation structure and the protecting layer interface a sidewall of the of the oxide layer, and a nitrogen concentration of the protecting layer is greater than a nitrogen concentration of the low nitrogen dielectric layer. In some embodiments, a first interface of the gate structure and the protecting layer is lower than a second interface of the gate spacer and the protecting layer. In some embodiments, in a top view, the semiconductor fin base and the backside conductive feature extend lengthwise along a same direction.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a stack on a substrate, the stack comprising a plurality of first semiconductor layers interleaved by a plurality of second semiconductor layers;
patterning the stack and a top portion of the substrate to form a first active region and a second active region protruding from a bottom portion of the substrate and extending lengthwise in a direction, the first active region comprising a first fin base and a first stack of semiconductor layers over the first fin base, the second active region comprising a second fin base and a second stack of semiconductor layers over the second fin base;
forming an isolation structure between the first active region and the second active region;
depositing a protecting layer on the isolation structure;
forming a dummy gate stack across the first active region and the second active region, the dummy gate stack interfacing a top surface of the protecting layer;
depositing gate spacers on sidewalls of the dummy gate stack;
recessing the first and second active regions outside of the dummy gate stack and the gate spacers to form a first trench and a second trench, respectively;
forming a first source/drain feature in the first trench and a second source/drain feature in the second trench, wherein a portion of the first source/drain feature overhangs the isolation structure, wherein a portion of the second source/drain feature overhangs the isolation structure;
removing the dummy gate stack to form a gate trench, the gate trench exposing the protecting layer;
removing the second semiconductor layers from the gate trench;
depositing a gate structure in the gate trench, the gate structure interfacing the top surface of the protecting layer;
forming a source/drain contact disposed over and connected to the first source/drain feature;
thinning the substrate to expose a back side of the isolation structure;
forming a backside dielectric structure on the back side of the isolation structure;
forming a backside opening through the backside dielectric structure and exposing a bottom surface of the protecting layer, a bottom surface of the source/drain contact, and sidewalls of the gate spacers; and
forming a conductive feature in the backside opening and electrically connected to the source/drain contact.

2. The method of claim 1, wherein the isolation structure interfaces a sidewall of the first fin base and a sidewall of the second fin base.

3. The method of claim 1, wherein the source/drain contact is disposed over and connected to the second source/drain feature.

4. The method of claim 1, further comprising:
forming a first dielectric layer along a sidewall of the first fin base; and
forming a second dielectric layer along a sidewall of the first dielectric layer,
wherein the first dielectric layer and the second dielectric layer are between the isolation structure and the first fin base,
wherein the first dielectric layer comprises less than about 10% nitrogen, and
wherein the second dielectric layer comprises an oxide.

5. The method of claim 1, wherein removing the dummy gate stack further removes a top portion of the protecting layer and a bottom portion of the protecting layer remains.

6. The method of claim 1, wherein the first trench and the second trench extend through the protecting layer and expose the isolation structure.

7. The method of claim 6, wherein a top portion of the first trench adjacent to the gate spacers has a first width along the direction,
wherein a bottom portion of the first trench spanning between sidewalls of the isolation structure has a second width along the direction, the second width greater than the first width.

8. The method of claim 7, wherein a middle portion of the first trench adjacent to the protecting layer and between the top portion and the bottom portion has a third width along the direction, the third width less than the second width.

9. The method of claim 1, wherein thinning the substrate removes at least a bottom portion of the isolation structure.

10. A method, comprising:
providing a structure comprising a substrate and a fin-shaped structure protruding from the substrate;
forming an isolation structure over the substrate and adjacent to a sidewall of the fin-shaped structure;
forming a protecting layer on the isolation structure;
epitaxially growing a source/drain feature on a source/drain region of the fin-shaped structure;
depositing a contact etch stop layer (CESL) over the source/drain feature;
depositing a first interlayer dielectric (ILD) layer over the CESL;
depositing a capping layer over a top surface of the CESL and a top surface of the first ILD layer;
depositing a second ILD layer over the capping layer;
forming a source/drain contact plug disposed in the first ILD layer to electrically couple to the source/drain feature;
forming a metal silicide layer disposed between the source/drain feature and the source/drain contact plug, wherein an electrical conductivity of the metal silicide layer is between an electrical conductivity of the source/drain feature and an electrical conductivity of the source/drain contact plug, wherein the metal silicide layer comprises a curved profile;
thinning down the substrate from a bottom of the structure until the isolation structure is exposed;
forming an opening exposing a bottom surface of the source/drain contact plug and a bottom surface of the protecting layer; and
depositing a backside conductive feature in the opening.

11. The method of claim 10, wherein the fin-shaped structure comprises a fin base and a stack of channel layers and sacrificial layers; and
wherein the method further comprises:
forming a dummy gate structure over a channel region of the fin-shaped structure,
after depositing the first ILD layer, removing the dummy gate structure and the sacrificial layers to form a gate trench, and
forming a gate structure in the gate trench and wrapping around the stack of channel layers, wherein the gate structure is disposed on a top surface of the protecting layer opposite to the bottom surface of the protecting layer.

12. The method of claim 11, wherein the fin-shaped structure extends lengthwise along a direction, and
wherein a portion of the backside conductive feature is spaced apart from the gate structure by a gate spacer along the direction.

13. The method of claim 11, wherein removing the dummy gate structure and the sacrificial layers further removes a top portion of the protecting layer in the gate trench, such that the top surface of the protecting layer has a concaved profile.

14. The method of claim 10, wherein epitaxially growing the source/drain feature comprises:
forming a source/drain recess in the source/drain region of the fin-shaped structure; and
epitaxially growing the source/drain feature in the source/drain recess,
wherein forming the source/drain recess removes a portion of the protecting layer to expose the isolation structure.

15. The method of claim 14, wherein forming the opening removes portions of the isolation structure, the CESL, and the first ILD layer.

16. The method of claim 10, wherein before thinning down the substrate, the ILD layer comprises a bottom portion embedded in the isolation structure and a top portion above the bottom portion,
wherein the bottom portion is wider than the top portion along a lengthwise extending direction of the fin-shaped structure.

17. A semiconductor structure, comprising:
one or more nanostructures disposed over a semiconductor fin base;
an isolation structure disposed on a side of the semiconductor fin base;
a protecting layer disposed on the isolation structure and below a bottommost surface of the one or more nanostructures;
first and second source/drain features connected by the one or more nanostructures;
a gate structure disposed over the one or more nanostructures and interfacing a top surface of the protecting layer;
a gate spacer extending along a sidewall of the gate structure and interfacing the top surface of the protecting layer;
a source/drain contact disposed over and electrically coupled to the first source/drain feature, wherein an electrical conductivity of the source/drain contact is greater than an electrical conductivity of the first source/drain feature; and
a backside conductive feature landing on a bottom surface of the protecting layer and a bottom surface of the source/drain contact,
wherein the backside conductive feature is electrically isolated from the gate structure by the gate spacer and the protecting layer.

18. The semiconductor structure of claim 17, further comprising:
a low nitrogen dielectric layer disposed on a sidewall of the semiconductor fin base; and
an oxide layer and disposed on a sidewall of the low nitrogen dielectric layer,
wherein the isolation structure and the protecting layer interface a sidewall of the of the oxide layer, and
wherein a nitrogen concentration of the protecting layer is greater than a nitrogen concentration of the low nitrogen dielectric layer.

19. The semiconductor structure of claim 17, wherein a first interface of the gate structure and the protecting layer is lower than a second interface of the gate spacer and the protecting layer.

20. The semiconductor structure of claim 17, wherein in a top view, the semiconductor fin base and the backside conductive feature extend lengthwise along a same direction.
